(19) United States
(12) Patent Application Publication
(10) Pub. No.: US 2013/0133934 A1
(43) Pub. Date: May 30, 2013

(54) BIOCOMPATIBLE CONDUCTIVE INKS

(71) Applicants: Glen P. Flores, Gainesville, FL (US); Christopher D. Batich, Gainesville, FL (US)

(72) Inventors: Glen P. Flores, Gainesville, FL (US); Christopher D. Batich, Gainesville, FL (US)

(73) Assignee: UNIVERSITY OF FLORIDA RESEARCH FOUNDATION, INC., Gainesville, FL (US)

(21) Appl. No.: 13/580,835

(22) PCT Filed: Feb. 23, 2011
(86) PCT No.: PCT/US2011/025937

§ 371 Date: Nov. 12, 2012

Related U.S. Application Data
(60) Provisional application No. 61/307,090, filed on Feb. 23, 2010.

(51) Int. Cl. C09D 11/00; H05K 1/09

(52) U.S. Cl. CPC C09D 11/52; H05K 1/097
USPC 174/257; 252/500; 252/514; 427/58

(57) ABSTRACT

This invention relates to compositions and methods related to biocompatible conductive inks. In a preferred embodiment the inks are printable onto biocompatible substrates and are used in the creation of biocompatible medical devices, in general, the inks comprise a plurality of particles. In one embodiment, the particles have a particle surface and an agent on the particle surface, the agent configured to prevent the particles from agglomerating when the particles are in a solution, the agent also configured to allow adjacent particle surfaces to be in contact when the particles are not in the solution due to an opening in the agent.

### RELATED APPLICATION

This application claims priority to provisional patent application Ser. No. 61/307,090 filed on Feb. 23, 2010, which is incorporated by reference herein in its entirety.

### STATEMENT OF GOVERNMENT INTEREST

This invention was made with at least partial support from the U.S. government. Accordingly, the government has certain rights in the invention.

### FIELD OF THE INVENTION

The present invention is generally related to conductive, biocompatible particles and inks, processes for producing the conductive, biocompatible particles and inks, and substrates having the conductive, biocompatible inks printed thereon.

### BACKGROUND OF THE INVENTION

Medication compliance is the degree to which a medication is taken according to a prescribed treatment and is usually measured in terms of percent of doses taken over a given interval. It is estimated 125,000 people die of treatable ailments because of poor adherence and a tenth of hospital admissions are associated with noncompliance at a healthcare services expense of approximately $15.2 billion annually. Medication compliance is also important in the context of clinical drug trials, geriatrics, and mental health/addiction medicine. For example, in a clinical drug trial it is desirable to know, with a high degree of certainty, the patient's compliance to a medication regimen because without such knowledge the results from a clinical trial cannot be accurately interpreted or could even be misleading. Conductive inks are available commercially from various sources. These inks, however, are not suitable for in vivo systems for the following reasons: (a) conductivity is too poor for use as high efficiency, ultra thin electronics and antennas; (b) sintering does not occur below 300° C.; (c) inkjet printing is difficult due to their inherently high viscosity and large particle size; and (d) the inks do not use non-biocompatible components. Nanoparticle inks, in particular, resolve only some of these issues. In particular, nanoparticle inks can be inkjet printed because of their small size (no clogging), permitting the creation of very thin conductive lines. Silver nanoparticles exhibit a sharp increase in electrical conductivity (up to 50% the conductivity of pure silver metal) when they are heated above their sintering temperature, which is typically between 150 and 300° C., much below the melting point of bulk silver (962° C.). Advances in nanoparticle synthesis allow for the creation of highly pure (>96% pure), metallic nanoparticles for use in printing fine-line conductive traces with high conductivity. These formulations have been utilized for the creation of antennas (particularly for RFID tags) and printed electronics on polymers substrates, such as Kapton, ceramic substrates such as glass, and various semiconductors.

Nanoparticle inks as described in the literature, however, do not solve all of the problems for creating biocompatible conductive inks. For instance, at temperatures less than 150° C., standard, high-yield nanoparticles do not typically sinter and are not biocompatible. In addition, at high sintering temperatures, most biocompatible substrates such as polyethylene terephthalate or polymethylmethacrylate will degrade, melt, or warp. Silver metallization through sintering of silver nanoparticles depends on a time-temperature thermal treatment. The majority of conductive ink technology requires sintering at high temperatures for significant amount of time. A common sintering treatment is 250° C. for 15-30 minutes, for example. For curing temperatures lower than 150° C., the particles conduct very poorly due to the presence of protective polymers (if present) and the lack of sufficient thermal energy to begin the sintering process. This number typically exceeds 1 Ω-cm, as compared to 1.6×10-6 Ω-cm for bulk silver. These reported conductivities are typically far too high for thin, small ingestible biotelemetry.

Dearden et al. showed that silver nanoparticle films could create conductive silver tracks from 125° C.-200° C.; however, at 125° C., the conductive tracks had a resistivity 106 times that of bulk silver, which would make very poor electronics. Conductive lines printed with unsintered nanoparticles, without a chemical metallization treatment, would lack film stability and thus would dissolve upon exposure to body fluids. Perelaer et al. has shown partial sintering of silver nanoparticles at 130° C. by starting with a completely liquid inkjet solution containing silver on (no nanoparticles). While that study was able to reach conductivity about 4 times that of bulk silver, the subsequent nanoparticles upon sintering were poorly metallized, with noted agglomerates rather than metal film, which may lead to biocompatibility problems.

A method of producing metal nanoparticles in colloidal solutions is known. In this method, the surface of a metal particle is protected with a polymer. The polymer prevents the metal particles from agglomerating and also allows the size of the nanoparticles to be controlled. This approach presents a dilemma, however. While using protective polymers prevents agglomeration and allows for controllable particle size, the protective polymers also electrically insulate the metal portions of the particles. Since the metal portions are insulated, electricity cannot efficiently be conducted between adjacent particles. This clearly is not a desirable property for conductive inks. Therefore, there is a need in the art for conductive inks that are biocompatible and have low resistivity and can be produced via reliable techniques.

### SUMMARY OF THE INVENTION

The present invention is directed to compositions and methods related to biocompatible conductive inks that satisfy the need for biocompatible conductive inks with low resistivity. When printed on an ingestible product or a product that can be inserted into the body, these biocompatible, conductive inks can enable electronic monitoring of the product.

According to one aspect of an embodiment of the invention a composition comprising a plurality of particles having a particle surface and an agent on the particle surface, the agent configured to prevent the particles from agglomerating when the particles are in a solution, the agent also configured to allow adjacent particle surfaces to be in physical contact when the particles are not in the solution due to an opening in the agent is provided. In certain embodiments the particles are micro or nanoparticles. The agent can have a plurality of chain lengths that are multimodal in distribution. In one example, the plurality of chain lengths are bimodal in distribution and the average chain length of a bimodal distribution of the agent is approximately 100 and approximately 400. The particle can contain a conductor such as a metal, for example. Suitable metals include, but are not limited to, at least one of silver, gold, copper, platinum, zinc, tin, iron, nickel, lead, magnesium, palladium, cobalt, aluminum, chromium or a combination thereof.

In certain embodiments of the composition, agent is capable controlling particle growth, which includes the particle geometry such as size and shape. The agent can be any number of materials such as a polymer, a lipid, a fatty acid, a protein, a cellulosic material or a combination thereof. In certain specific embodiments, the agent is a polyvinylpyrrolidone polymer (PVP) or a derivative thereof. The adjacent conductor surfaces can be in electrical contact through an opening in the agent and the electrical contact can be improvable by heating. The composition can also further comprise a biocompatible substrate.

Certain embodiments of the composition allow for the electrical properties of the composition to be improved by curing or sintering the particles at a temperature of less than 150° C.

In one preferred embodiment of the composition the composition comprises a plurality of particles having a particle surface and an agent on the particle surface; and wherein the agent contains a multimodal distribution of chain lengths, the agent is configured to prevent the particles from agglomerating when the particles are in a solution and the agent is configured to control the geometry the particles. According to a more specific embodiment, the plurality of chain lengths are bimodal in distribution and the average chain length of a bimodal distribution of the agent is approximately 100 and approximately 400.

A process for producing coatings, fillers, or inks according to another embodiment of the invention comprises forming particles in a solution, the particles having a particle surface and an agent on the particle surface; removing the particles from the solution; and wherein the agent is configured to prevent the particles from agglomerating in the solution, the agent is configured to control the particle geometry and the agent is configured to allow adjacent particle surfaces to be in contact when the particles are not in the solution. The agent can be composed of a multimodal distribution of chain lengths, such as a bimodal distribution and the average chain length of a bimodal distribution of the agent is approximately 100 and approximately 400. The agent can further be configured to control particle growth, such as controlling particle growth in a colloidal solution. In certain more specific embodiments the process further comprises preparing an aqueous solution of a conductor source and the agent; reducing the conductor source to a conductor; and allowing the agent to associate with the particle surface to form part ides.

In even more specific embodiments, the particles are silver particles, and the forming further comprises mixing a reducing agent into the aqueous solution and adding a 20-75% wiw pH modifier to increase the pH of the aqueous solution. In a preferred embodiment of the process, the conductor source is AgNO₃ a mass ratio of NaOH to AgNO₃ is from 1:30 to 30:1. As with the compositions described above, the particle can be a conductor such as a metal. Suitable conductor sources include, but are not limited to, at least one of a silver source, a gold source, a copper source, a platinum source, a zinc source, a tin source, an iron source, a nickel source, a magnesium source, a palladium source, a cobalt source, an aluminum source, a chromium source or a combination thereof.

In other specific embodiments the mass ratio of the multimodal agent to the conductor source is 2:1. The agent can be a multimodal polymeric agent such as PVP or a derivative thereof.

The forming process can further comprise preparing an aqueous solution of PVP10 and PVP40 in a vessel and adding an amount of a conductor source to the aqueous solution, in a preferred embodiment the ratio of the PVP10 to the PVP40 is 10:1 to 1:10 and wherein the particles have a particle size of 1-200 nm. In other embodiments, the process further comprises centrifuging the solution for a time sufficient to produce a plurality of particles and a supernatant in a vessel; removing the supernatant from the vessel to leave the plurality of particles within the vessel; washing the particles with a washing liquid to remove excess agent; and wherein the centrifuging is completed in less than 5 minutes. The particles formed according to the process can be curable or sinterable at a temperature of 190° C. or less.

The process can be extended to make a conductive and biocompatible ink of the particles such as by mixing the particles with biocompatible binders biocompatible release agents, rheology modifiers, suspension agents, solvents or a combination thereof. Preferred binders and solvents include but are not limited to a propylene glycol solution, α-terpineol, ethylcellulose or a combination thereof.

According to another aspect of an embodiment of the invention, a biocompatible ink is provided. The bio compatible ink comprises a plurality of substantially non-agglomerated conductive nanoparticles and a unimodal or multimodal mixture of a biocompatible protective agent.

According to another aspect of an embodiment of the invention, a process for producing a biocompatible conductive ink is also provided and comprises mixing a biocompatible agent and a conductive source in an aqueous solution for a time sufficient to form a plurality of biocompatible conductive particles; recovering the conductive particles from the aqueous solution; and whereinthe agent is configured to prevent the particles from agglomerating in the solution and the agent is configured to control the particle geometry. The conductive particles can further be mixed with a biocompatible binder such as a-terpineol, ethylcellulose, propylene glycol or a combination thereof. This process can further comprise combining the conductive particles with a second agent selected from a biocompatible release agent, a rheology modifier, a suspension agent, a solvent or a combination thereof. In a specific embodiment, the agent is a bimodal mixture of PVP containing a mixture of PVP having an average chain length of 100 (PVP10) and PVP having an average chain length of 400 (PVP40).

According to another aspect of an embodiment of the invention a biocompatible film is provided. The biocompatible film comprises a plurality of substantially non-agglomerated metal nanoparticles, wherein the plurality of substantially non-agglomerated nanoparticles have an electrical resistivity of 1 Ω-cm or less and are sintered to form a film; and wherein the biocompatible film is ingestible.

According to another aspect of an embodiment of the invention a printed biocompatible article is provided and comprises a biocompatible substrate having a biocompatible ink printed thereon in a predetermined pattern; and wherein the biocompatible ink comprises a plurality of conductive particles. The biocompatible substrate can be comprises at least one of gelatin, cellulose acetate phthalate, polyethylene terephthalate, polymethylmethacrylate, hyprornellose or a combination thereof; for example. The biocompatible substrate that can also be dissolvable at a pH greater than 5 in certain embodiments. The printed biocompatible article can further include an integrated circuit or microchip for producing a transmittable signal from the biocompatible ink. A power source can be in communication with the integrated circuit or microchip.

According to another aspect of an embodiment of the invention a process for creating ingestible nano- or micro-particle inks comprised of sintered particles or particles connected to each other using binding agents that do not release non-biocompatible agents or non-biocompatible particles that are coated with metal or other agent that can retain non-biocompatible particles is provided.

According to another aspect of an embodiment of the invention a composition comprising a conductive nano- or micro-particle ink with a multimodal agent on a surface of the particles that provides for increased conductivity and lower sintering temperatures is provided.

According to another aspect of an embodiment of the invention a nano- or microparticle ink is provided that can be placed onto a substrate and sintered at a temperature that is less than a temperature at which the substrate degrades, has a resistivity of 1 Ω-cm or less after being sintered or cured or dried and is biocompatible.

According to another embodiment of the invention an electronic device is provided. The electronic device comprises a conductive trace printed on a biocompatible substrate, the conductive trace containing a plurality of particles, each particle having a conductor, a conductor surface and an agent on the conductor surface, wherein adjacent conductor surfaces are in electrical contact through at least one opening in the agent. In the electronic device the agent can be a multimodal mixture of polymer, for example. In another embodiment of an electronic device of the invention, the electronic device comprises a first conductive trace consisting of a plurality of printed nanoparticles or microparticles of a first species; a second conductive trace consisting of a plurality of printed nanoparticles or microparticles of a second species; and wherein the two traces produce a galvanic cell capable of producing electrical current and voltage. The first substance can be a metal, metallic compound, or graphite and the second substance can be a different metal, metallic compound or graphite. The particle can contain a conductor. In a preferred embodiment, the conductor is a metal, such as at least one of silver, gold, copper, platinum, zinc, tin, iron, nickel, lead, magnesium, palladium, cobalt, aluminum; chromium or a combination thereof.

These and other objects, aspects, and advantages of the present invention will be better appreciated in view of the drawings and following detailed description of the preferred embodiment.

### BRIEF DESCRIPTION OF THE DRAWINGS

FIG. 1 is a graph of CPSC particle size distribution for SNPs formed by All-PVP40;

FIG. 2 is a graph of CPSC particle size distribution for SNPs formed by PVP40:PVP10=5:1;

FIG. 3 is a graph of CPSC particle size distribution for SNPs formed by PVP40:PVP10=2:1;

FIG. 4 is a graph of CPSC particle size distribution for SNPs formed by PVP40:PVP10=1:2;

FIG. 5 is a graph of CPSC particle size distribution for SNPs formed by PVP40:PVP10=1:5;

FIG. 6 is a graph of CPSC particle size distribution for SNPs formed by All-PVP10;

FIG. 7 is a graph of mass loss of PVP from SNPs as a function of temperature:

FIG. 8 is a TEM micrograph of SNPs formed by a reaction using All-PVP40;

FIG. 9 is a TEM micrograph of SNPs formed by a reaction using PVP40:PVP10=5:1;

FIG. 10 is a TEM micrograph of SNPs formed by a reaction using PVP40:PVP10=2:1;

FIG. 11 is a TEM micrograph of SNPs formed by a reaction using PVP40:PVP10=1:2;

FIG. 12 is a TEM micrograph of SNPs formed by a reaction using PVP40:PVP10=1:5;

FIG. 13 is a TEM micrograph of SNPs formed by a reaction using All-PVP10;

FIG. 14 is graph of resistivity vs. PVP40:PVP10 for run A;

FIG. 15 is graph of resistivity vs. PVP40:PVP10 for run B;

FIG. 16 is graph of resistivity vs. PVP40:PVP10 for run C;

FIG. 17 is a SEM micrograph of SNPs formed by All-PVP40 and sintered at 160° C.;

FIG. 18 is a SEM micrograph of SNPs formed by All-PVP40 and sintered at 190° C.;

FIG. 19 is a SEM micrograph of SNPs formed by PVP40:PVP10=5:1 and sintered at 160° C.;

FIG. 20 is a SEM micrograph of SNPs formed by PVP40:PVP10=5:1 and sintered at 190° C.;

FIG. 21 is a SEM micrograph of SNPs formed by PVP40:PVP10=2:1 and sintered at 160° C.;

FIG. 22 is a SEM micrograph of SNPs formed by PVP40:PVP10=2:1 and sintered at 190° C.;

FIG. 23 is a SEM micrograph of SNPs formed by PVP40:PVP10=1:2 and sintered at 160° C.;

FIG. 24 is a SEM micrograph of SNPs formed by PVP40:PVP10=1:2 and sintered at 190° C.;

FIG. 25 is a SEM micrograph of SNPs formed by PVP40:PVP10 and sintered at 160° C.;

FIG. 26 is a SEM micrograph of SNPs formed by PVP40:PVP10=1:5 and sintered at 190° C.;

FIG. 27 is a SEM micrograph of SNPs formed by All-PVP10 and sintered at 160° C.;

FIG. 28 is a SEM micrograph of SNPs formed by All-PVP10 and sintered at 190° C.;

FIG. 29 is a graph of the IV characteristics of a SNP film produced by PVP40:PVP10=2:1 where the sample was heated to and measured at 115° C.;

FIG. 30 is a graph of the IV characteristics of a SNP film produced by PVP40:PVP10=1:5 where the sample was heated to and measured at 115° C.;

FIG. 31 shows AFM micrographs for the same region of PVP10-synthesized SNPs where a) is contact mode micrograph and b) is phase shift micrograph and the scale bar in a) indicates the height of the surface (in nm) of the SNP and the scale bar in b) indicates the phase shift (in degrees) due to tip-sarnple interactions;

FIG. 32 shows AFM micrographs for the same region of PVP40-synthesized SNPs where a) is contact mode micrograph and b) is phase shift micrograph and the scale bar in a) indicates the height of the surface (in nm) of the SNP and the scale bar in b) indicates the phase shift (in degrees) due to tip-sample interactions;

FIG. 33 shows images of pad-printed antennae using SNPs;

FIG. 34 is a graph of the DOE results for particle size distribution;

FIG. 35 is an image of an antenna pattern printed using SNP ink;

FIG. 36 is a graph of silver concentration in various solutions and calibration standards; and

FIG. 37 is a graph of silver concentration in various solutions and calibration standards.

### DETAILED DESCRIPTION OF THE PREFERRED EMBODIMENT

In the Summary of the Invention above and in the Detailed Description of the Invention and in the accompanying drawings, reference is made to particular features (including method steps) of the invention. It is to be understood that the disclosure of the invention in this specification includes all possible combinations of such particular features. For example, where a particular feature is disclosed in the context of a particular aspect or embodiment of the invention, that feature can also be used, to the extent possible, in combination with and/or in the context of other particular aspects and embodiments of the invention, and in the invention generally.

The term “comprises” is used herein to mean that other ingredients, ingredients, steps, etc. are optionally present. When reference is made herein to a method comprising two or more defined steps, the steps can be carried in any order or simultaneously (except where the context excludes that possibility), and the method can include one or more steps which are carried out before any of the defined steps, between two of the defined steps, or after all of the defined steps (except where the context excludes that possibility).

In this section, the present invention will be described more fully with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will convey the scope of the invention to those skilled in the art. Like numbers refer to like elements throughout, and prime notation is used to indicate similar elements in alternative embodiments.

The present inventors have addressed the needs of the prior art by providing processes for producing biocompatible, conductive particles and the novel products of the processes that are easily printable, do not agglomerate, and have a relatively low metallization temperature. In general, the compositions of the present invention are composed of a plurality of particles. Each particle comprises a conductor, such as a metal, a conductor surface and an agent associated with the conductor surface. The agent is configured to serve several functions. The agent can be associated with the conductor surface by a chemical bond, for example such that when the particles are in a solution, such as a colloidal solution, the agent prevents the particles from agglomerating. But when the particles are dry, the agent also allows adjacent conductor surfaces to be in electrical contact. By allowing the adjacent conductor surfaces to be in electrical contact when the particles are dry, the resistivity of the ink can be decreased relative to the nanoparticle conductive inks known in the art, especially once the ink is heated to a desired temperature such as a curing or sintering temperature. Thus, agents that will cover a portion but not all of the surface of the dry particles are preferred. In this preferred embodiment, the agent allows the adjacent conductor surface to be in electrical contact through at least one opening in the agent which exposes the conductor surface. Many different agents can be selected to serve these purposes. In the description below, the inventors show that a bimodal molecular weight polymer can serve as such an agent.

In one embodiment, metallic, e.g., silver, nanoparticles were produced by reducing a conductor source, such as metal ions (Ag⁺, for example), to metallic particles in the presence of a protecting agent, which in one embodiment consists of two different molecular weight molecules. In a preferred embodiment, the molecules are PVP molecules or derivatives thereof. In a preferred embodiment the agent is PVP10, having an average molecular weight of approximately 10,000 and chain length of approximately 100, and PVP40, having an average molecular weight of approximately 40,000 and chain length of approximately 400. Using this novel bimodal chain length PVP-protecting agent, silver nanoparticles were produced that were able to achieve a lower electrical resistivity than was previously reported in the literature for silver nanoparticles cured at temperatures below their sintering temperature. Silver nanoparticles could be produced in the size range of 20-200 nm and could be pad printed into high-resolution antenna patterns. Moreover, after applying heat at a temperature of 60° C. for 10 minutes, the electrical resistivity of silver nanoparticles was as low as 4.0×10⁻³ Ω-cm.

Electrical resistivity as low as 7.4×10Ω-cm could further be achieved in these nanoparticles at a sintering temperature of 190° C. for a sintering time of as little as 10 min. Silver nanoparticle inks produced using the above-mentioned silver nanoparticles also exhibited large differences in electrical resistivity depending on the respective molecular weight of PVP used during nanoparticle synthesis. After 10 minutes of a 115° C. heat treatment, for example, a four orders of magnitude (or greater) difference in resistivity could be observed between silver nanoparticles synthesized by the bimodal MW PVP system relative to either PVP of molecular weight 40,000 alone.

Although numerous examples of the formation and use of silver nanoparticles and silver nanoinks are set forth herein, it is understood that the present invention is not so limited to silver nanoparticles and silver inks. It is understood that the bimodal protective agent system, such as PVP 10K/40K MW, may be utilized with other conductive species, e.g., other conductive metals, to prepare suitable particles and inks having conductive properties. The particles can be microparticles rather than nanoparticles, or they can be a combination thereof. These species include environmentally stable metals gold, platinum, and palladium as well as other stable metals such as nickel, copper, zinc, and the like. The particles can be adapted for specific purposes through chemical techniques. For example, the particles can be adjusted in toughness, ductility, strength, modulus, strain, shear strength, compressive strength, luster, color, hardness, porosity and density, among other properties, through the use of additives such as other metallic elements like alloys, surface modifiers, porosity modifiers, sintering temperature modifiers, colorants, plasticizers, reducing agents, protective agents and so forth.

Further, the molecular weights of the protective agent, such as a polymer, can be adjusted. Although the specific examples discussed herein deal with molecular weights on the order of tens of thousands, this molecular weight range is not necessary for all embodiments. Very small molecular weight molecules, such as a molecule having one carbon chain length, are also embodied in the invention.

U.S. Patent Application Pub No. 2010/0009071 discloses the use of bimodally sized particles, wherein a smaller size particle was protected and a larger sized particle was not. In contrast, in the present invention, all of the particles have protective agents associated with their conductor surfaces. Accordingly, this invention utilizes bimodal protective agents and small molecular weight protective agents that both protect the conductors and allow for the creation of open faces that expose a portion of the conductor surface.

To identify the reasons for the difference in electrical resistivity between silver nanoparticles produced by each respective molecular weight, the surface topology of silver nanoparticles was imaged using atomic force microscopy as described further in detail below. Atomic force microscopy revealed that, upon drying at room temperature, silver nanoparticles decorated with PVP of molecular weight 10,000 had numerous areas of exposed silver. These exposed silver areas could then allow silver-to-silver contact between nanoparticles, which would allow for a highly conductive electrical pathway between particles. Silver nanoparticles decorated with PVP of molecular weight 40,000 alone, however, exhibited very few areas of exposed silver, indicating that PVP coated the samples extensively. Thus, highly conductive pathways were unavailable in these nanoparticles, leading to poor electrical conduction. The multimodal protective agent does not have to be the same material; for example, polyvinyl alcohol can be used with PVP, each having their distinct molecular weight and/or protective properties

In accordance with one aspect of the present invention, there is provided silver nanoparticles having a particle size of from 1-200 nm and an electrical resistivity of 4.0(10)⁻³ Ω-cm or less after heat treatment of the silver nanoparticles at 190° C. or less.

In accordance with another aspect of the present invention, there is provided a biocompatible ink comprising a plurality of nanoparticles. The nanoparticles have a particle size from 1-200 nm and have an electrical resistivity of 4.0×10⁻³ Ω-cm or less after heat treatment at curing at 190° C. or less. One novel aspect of the current particles is that they may have substantially lower conductivity values than those in the prior art. For example, the literature describes polymer-protected nanoparticles that show a resistivity of 10⁻¹ Ohm-cm when cured at 130° C. Thus, the present invention provides polymer-protected nanoparticles with lower resistivity values after curing.

In accordance with another aspect of the present invention, there is provided a method for producing a conductive, biocompatible ink comprising: (a) mixing a bimodal mixture of a protective agent (e.g. PVP) and a metallic source in an aqueous solution for a time sufficient to form a plurality of metallic nanoparticles; and (b) recovering the metallic nanoparticles from the aqueous solution. In the method, the bimodal mixture of protective agent comprises a mixture of PVP having an average molecular weight of 10,000 (PVP-10) and PVP having an average molecular weight of 40,000 (PVP-40). Also, in the method, the mixture comprises any suitable ratio of PVP-10 and PVP-40, such as from 1000:1 to 1:1000 PVP-10 to PVP-40. In particular embodiments, the ratio of the PVP-10 to the PVP-40 is from 1:5 to 5:1, preferably 2:1 to 1:2, and more preferably 1:1.

With a low metallization temperature, the biocompatible inks of the present invention can be printed on substrates, e.g., biocompatible substrates such as polyethylene terephthalate or polymethylmethacrylate, which to date, could not withstand the metallization temperatures of the inks. Accordingly, in another aspect of the present invention, there is provided a tagged substrate comprising a biocompatible ink comprising a plurality of nanoparticles and a substrate having a nanoink printed thereon. The biocompatible ink has a metallization temperature at which the substrate will not deform or degrade, e.g., the metallization temperature of the ink is less than a glass transition temperature of the biocompatible substrate.

While the present application discusses the use of the biocompatible inks with biocompatible substrates for medication compliance, this use is merely exemplary. It is understood that the biocompatible inks as described herein may be used for any other purpose and may be printed on any substrate, wherein the biocompatible ink has a metallization temperature at which such substrate will not deform or degrade. Other suitable substrates may include fruit, vegetables, or other substrates. Use of the inks is not limited to ingestible devices. The inks can also be used on biomedical implants on various biocompatible substrates for any number of uses such as electrodes, sensor probes, etc. The inks can be used in combination with polymers or other materials that enhance sensitivity for various elements. Suitable biocompatible substrates include, but are not limited to, PET, PTFE, polycarbonate and polyimide.

Another application of the invention is with resistance-changing metal nanoparticle traces that exhibit a change in resistance when a stimulus that will cause the particles to change from a nanoparticle to a sintered state, such as heat, high current, high voltage, or the like is applied. These can help identify electrical discharge (from static or other electricity) or thermal changes. When there is no discharge or heat, the traces remain electrically conductive, but the electrical conductivity increases when the traces are discharge. Applications include fuses that drive current away from fragile electric components, sensors for static-sensitive components, self-sintering electronics, sensors for electrically sensitive components, etc

Another application of the invention is to make capacitive diagnostic strips having conductive ink on opposing strips acts to as a conductive plate. The electrical properties outside of capacitance, resistance, etc. can also be changed in response to stimuli from the environment. Suitable stimuli include various antibodies/antigens, cells, chemical, proteins, or other molecules or elements that can bind or migrate to the surface of the strips. The strips can be dressed with various receptors as well. These can be used to diagnose or analyze blood, urine, saliva, breath, body fluids, gastrointestinal fluids and chemicals, for example. The ink on the diagnostic strips can be sintered or not. Sintering can be induced via chemical change from outside bodies. The strips can then be analyzed chromatographically, electrically, magnetically, etc. or the strips can have electrical or optical properties that can be disrupted by chemicals, cells, etc. The system can be used in combination with polymers or other materials that enhance sensitivity for various elements.

The ink can also be used in conjunction with markers, biological or not, to help track the ink through things such as the human body. Dyes, fluorescent dyes, identification markers and rare earth elements, for example, can be used as the marker.

In one embodiment, the substrate is a dissolvable, biocompatible substrate that will substantially to completely dissolve in a solution with a pH in the range of 1-7.4. In this way, when the biocompatible ink is printed on the dissolvable, biocompatible substrate and is introduced into a subject in vivo, the substrate may dissolve with the subject, e.g., within the gastrointestinal tract of the subject leaving behind only the sintered nanoink (or portions thereof) and other necessary components to be associated with the dissolvable substrate, such as a microchip or power source, as set forth below.

In one particular aspect of the present invention, the present inventors have developed biocompatible nanoinks for use as electronic devices that have the ability to transmit signals from a biocompatible substrate, such as a gelatin pill within the digestive system to an external receiver (such as a belt pack). The small electronic devices may be printed on standard ‘0’ or ‘00’ sized capsules, for example, for low-cost and reliable detection schemes of orally ingestible electronic pills (E-pills). Orally ingestible electronic pills are disclosed in U.S. Pat. No. 7,796,043 and U.S. patent application Ser. No. 12/811,572, the contents of which are herein incorporated by reference in their entirety. In one embodiment, low melting temperature substrates (such as gelatin or other biocompatible polymers) are used as the substrates onto which the inks are printed. The melting or deformation temperature of these materials will set an upper limit for the sintering temperature of electronic devices. An electrical resistivity constraint exists due to the need for high-efficiency electronic devices, such as antennae, that can emit detectable signals from within the body without significant signal loss.

To produce a transmittable signal from the electronic device according to this invention, in one embodiment, the substrate may also include a suitable integrated circuit or microchip and a power source (which may or may not be part of the microchip).

As mentioned above, in a particular embodiment, the biocompatible nanoparticles and inks comprise silver nanoparticles and inks. A particularly useful characteristic of silver is that it exhibits the lowest electrical resistivity of any metal (1.59 mΩ-cm at 20° C.). In electronic components, this can lead to a higher Q (quality factor) in antennas. Silver nanoparticles (SNPs) also have a proven record as a printing ink that can create well-defined patterns (Lahti et al., 1999 and Lee et al., 2005). Current inkjet technology typically uses piezo printheads to deliver picoliter-sized droplets of silver or gold nanoparticles. Because these nanoparticles act effectively as pigment inks, the current state-of-the-art printing technology needs only to be adapted to large-scale printing on biodegradable substrates using a more suitable ink.

Printing the aforementioned electronic devices preferably require very thin lines (on the order of a few hundred microns) to conserve both conductor and substrate surface area. Fine designs help to keep conductor intake at a minimum. They also help to prevent an increase in pill dissolution time by allowing more pill surface area to be exposed to stomach fluid after ingestion. The biocompatible inks disclosed herein may be printed in a pattern onto the surface of readily available hard shell capsules, which may be predominantly gelatin, hypromellose (hydroxypropyl methylcellulose), or other biocompatible substrates, for example.

SNPs have been shown to display particle coalescence (sintering) at temperatures starting at 150° C.—about one-eighth that of silver's bulk melting temperature (961° C.). The literature shows sintered silver lines that could find use in microelectronic devices, with practical size limits in the low nanometer range (Bieri et al., 2003 and Dearden et al., 2005). For direct pill printing, sintering treatments must be kept to temperatures that will not cause melting or disintegration of gelatin capsules or any alternative biocompatible material. Such materials include poly-lactic acid, which then may be heated and glued to the surface of a capsule.

Protecting SNPs from uninhibited growth is preferred to maintain particle sizes that are small to allow particle sintering after they have been printed. Much scientific research has been invested into PVP polymer-controlled growth of SNPs. PVP protects silver by forming a Ag-PVP complex that limits silver growth (Lee et al., 2005, Chou and Ren, 2000). Under such conditions, stable silver colloids can be formed within the narrow size distribution of 20-70 nm, which also decreases the sintering temperature of the SNPs to below 200° C. Experiments with conductive silver lines were performed because silver material properties are well adapted for high-performance electronic devices and can also be easily adapted to pre-existing pad printing, screen-printing, and inkjet technology that are likely compatible with a variety of SNP ink compositions.

In a preferred embodiment, a satisfactory E-pill printing ink system includes the following characteristics: (a) sintering SNPs on external substrates should allow for significant coalescence of particles to produce a metal foil, which will exhibit decreased electrical resistivity over non-sintered particles; (b) SNP inks should be useable in printing systems that can print antenna line widths of 100 microns or smaller (SNPs should be small enough to create small features on antennas); (c) sintered silver inks should not cause health risks (such as silver-induced argyria, which is a skin discoloration associated with ingestion of silver); (c) and the manufacturability (cost, ease, speed of production, etc.) of SNPs for silver ink should be high as electronic devices may be applied to a large number of pills.

Another aspect of an embodiment of the invention is to create two sets of metal nanoparticles from two distinct elements or an element and a compound or two compounds and printing them in a non-overlapping manner. This creates a galvanic cell when immersed in liquid (containing ions or other conductive species). For example, one set of metal nanoparticles could be composed of silver (or silver chloride) and another set of metal nanoparticles could be composed of magnesium (or magnesium chloride). Each set of metal nanoparticles could be printed along separate traces and attached to a given set of electronics to provide power when the leads are placed in a conductive solution.

Each set of nanoparticle inks is biocompatible, both in the nanoparticles and the ink formulation, as described herein. The nanoparticles can be alloys to increase strength, corrosion resistance, materials stability, and other beneficial materials properties.

The nanoparticles used for the printed galvanic pair can be unimodal, bimodal, or multimodally protected. They may also have no protective agent, if necessary, and simply be mixed in a biocompatible ink formulation.”

The electrical resistivity required for the SNP electronic device is dependent on each device and the radiation efficiency necessary to transmit an E-pill signal from within the digestive system to an external receiver. The material properties, synthesis, printability, and biocompatibility of silver and silver conductive lines are discussed further below. Multiple experiments and characterizations were performed to identify the effect of reaction chemistry on both of these SNP characteristics. The results of these experiments are also discussed below.

### WORKING EXAMPLES

### Example 1

### Preparation of Nanoparticles

In the production of silver nanoparticles (hereinafter SNPs), the final conductive ink properties, including proper ink solvents, SNP size, and ink printability, were carefully considered. Many factors must be considered in materials selection, especially for E-pill applications where size and sintering effects may be related to final material biocompatibility. In the development of the inks of the present application, the following SNP criteria and preferences were considered: (a) SNPs below 200 nm were desired with a large portion (>90%) in the region below 100 nm for inking and/or sintering purposes; (b) relatively high solution molarity was desired to increase SNP output per reaction volume; (c) no non-biocompatible elements or compounds were to be part of the synthesis if they could not be rinsed out post-reaction; (d) reagents were to be low cost for manufacturing purposes; (e) reaction time was constrained to be less than 3 hours for manufacturability concerns (SNPs that could not be prepared quickly and repeatedly were avoided); (f) final PVP content in SNP ink was to remain below 5% to minimize the electrical resistivity of silver antennas when cured (as PVP is a poor conductor); (g) ink from SNPs had to show good printability with suitable features for the E-pill application (less than 50 microns in printed edge variation); (h) SNP ink should be re-suspendable in a variety of solvents to be useable in a variety of inking applications; (i) SNPs should be stable and suspendable for extended periods (a few months) to promote a long ink shelf life; (j) SNP film resistivity was tested for its minimum value for various SNP chemistries.

In one embodiment of a process for making a silver ink comprising silver nanoparticles, silver was reduced by HCHO (37% w/w solution) with PVP as a protective agent to assist in the removal of excess PVP. Using a larger molarity, naturally, will allow more SNPs to be created per reaction vessel volume. Critically, PVP of various molecular weights (MW) were used: 10,000, 40,000, and 55,000 (PVP10, PVP40, and PVP55, respectively; purchased through Sigma-Aldrich). A 50% w/w NaOH solution (Sigma-Aldrich) was also used.

In this exemplary embodiment, all reaction steps were performed in a fume hood due to toxic volatile compounds. The reaction steps included: (1) Adding deionized H₂O to a beaker; (2) Mixing PVP with deionized H₂O while stirring; (3) adding AgNO₃; (4) adding the HCHO solution; (5) Adding the NaOH solution; (6) Adding acetone to the mixture; (7) Centrifuge the product in tubes; and (8) Washing away any remaining solvent and loose particles with the next solvent.

The reagents may of course change in quantity depending on the experiment. SNPs from this procedure were mostly between 10 and 100 nm and were difficult to reclaim by centrifuge techniques. The limited solubility of PVP in acetone (Lee et al., 2005), though, forces SNPs to agglomerate and then separate from solution under centrifugation, removing all unreacted HCHO, sodium ions, hydroxyl, and silver ions after pouring off the supernatant.

The initial washing step consisted of adding acetone to the reaction solution volume. The resulting mixture was centrifuged to remove the vast majority of PVP, but this still did not remove enough PVP from the surface to promote the desired low electrical resistivity. Therefore, the washing step was repeated to re-suspend the particles and wash away more PVP. The solution was centrifuged again. Finally, the solution was washed twice with a mixture of acetone:isopropanol to remove any extra silver and allow for printing on many kinds of hydrophilic and hydrophobic surfaces. Particles can be re-suspended in water, isopropanol, or ethanol if kept wet following colloid precipitation. The washing process left relatively pure silver colloids.

An interesting behavior not noted in the literature was that ultrasonication and filtration were not enough to remove PVP for low temperature nanoparticle sintering. The present inventors have found that rigorous shaking of the resultant solution was necessary to achieve low electrical resistivity at low sintering temperatures. Neither sonication nor vortex shaking was able to remove enough excess PVP from the surface of SNPs to allow for digital multimeter readings below a few MO at temperatures below 100° C. This indicates that for PVP removal with the chemistry provided above, strong physical agitation is necessary.

After shaking, same line dimensions typically exhibited a drop in resistance of six-order of magnitude, dropping below the measurement limit of our digital multimeter. Thus, our electrical resistivity experiments were performed on shaken samples. Even with strong physical agitation, PVP is still believed to remain on the surface of the SNPs, which helped dispersion and allowed SNPs to suspend in a wide variety of solvents.

Coil Conformation.

The manner in which PVP limits the growth of SNPs is important in the understanding of SNP protection, Growth of SNPs was first thought to be regulated by a probable Ag₂O step that immediately re-dissolved and formed silver nuclei along a PVP chain. The nucleation step is governed by solution pH while particle size is dependent on the number of initial nuclei (as more nuclei results in a distribution of silver mass over a larger number of particles). The key step in this process is the ability for PVP to arrange itself in a manner that can completely protect growing silver nuclei.

### Example 2

### Bimodal PVP MW Reaction Systems and Effects on SNP Properties

To better resolve the effect of PVP MW and produce some practical results that can be applied to conductive ink technology, the present inventors investigated how bimodal PVP MW systems would affect particle size and final ink properties.

In early informal and preparatory experiments, an interesting property was noted: PVP10-synthesized SNPs had a tendency to conduct electricity at lower temperatures than PVP40-synthesized SNPs. At first, this observation was thought to be due to the inability of PVP to sufficiently protect SNPs during their growth process as explained in the literature (Chou and Lai, 2004). Insufficient protection would have led to large silver microparticles that had little PVP content. In that previous study, PVP of MW 8000 was found to be insufficient in the protection of SNPs in NaOH base compared to PVP of higher MW. These literature observations were not verified by imaging techniques to reveal if the particles were truly micron-sized or if another mechanism was at work that produced large particles, or even if they were produced at all.

In the reaction performed by the present inventors, very large particles could not be seen precipitating out of solution during the reaction. Some relatively large particles were present in PVP10-synthesized samples and in PVP40-synthesized samples to a lesser degree. This effect was shown in some bimodal MW systems, but only after a few conditions were met, as detailed below.

After a few centrifugations of the reclaimed SNPs, large particles could indeed be seen, but these particles were few in number (though larger in combined volume) and were not evident in the centrifuge tube before centrifugation. Large particles were more evident when using isopropanol/acetone instead of water/acetone as the washing liquid. They were also more numerous in PVP10-synthesized samples than PVP40-synthesized samples. Thus, they may be caused by insolubility effects coupled with centrifugation compression. Silver thin films could be produced flat and without these particles when samples were stirred and mixed with water as the primary solvent. Addition of isopropanol to these films would again cause clumps to appear. Again, this may have been due to insolubility with isopropanol. It may also have been due to a change in PVP conformation that caused PVP molecules to lock chains more closely under an altered solvent condition. When isopropanol was used in conjunction with propylene glycol (to modify the solvent evaporation rate) for printing, these large clumps were not found. With these basic observations, it is advantageous to use lower MW PVP in the production of SNPs, contrary to what the literature suggests (Chou and Lai, 2004). Bimodal systems of PVP combine the excellent conductivity of PVP10-synthesized SNPs with any particle-size controlling power of PVP40.

PVP10 and PVP40 were the chosen PVP MWs for this system. They differed significantly in electrical resistivity at a given sintering temperature as to warrant further investigation. The bimodal PVP MW system is able to help determine what is occurring in the result of centrifuged SNPs. The objective of these experiments was to: (a) record electrical resistivity as a function of PVP10-to-PVP40 mass ratio and sintering temperature; (b) identify PVP mass remaining to isolate if PVP is the cause of differences in electrical resistivity; (c) obtain particle size distributions of SNPs according to the PVP10-PVP40 ratio and identify if a correlation exists between size and resistivity; (d) identify the source of conductivity at various temperatures, whether by sintering or particle-to-particle contact; and (e) propose a possible mechanism for differences in electrical resistivity between samples containing a majority of either PVP10 or PVP40.

TEM and SEM can produce micrographs that identify particle morphology and size of SNPs formed by a bimodal PVP MW system. TGA is appropriate to find the mass loss of PVP in the system as a function of temperature. TGA can also aid in identifying at what temperature range the majority of PVP is lost. A centrifuge size analysis technique is helpful in identifying SNP size distributions and provides a second look at particle size distributions produced by the DOE to compare with size distributions produced by Nanotrac. Four-point probe tests measure the sheet resistance of silver films.

The major objective of this series of experiments was to determine what type of PVP or PVP combination is best to create conductive electronic devices for biocompatible substrates.

Three different runs of bimodal PVP MW were prepared, each at different PVP10 to PVP40 mass ratios. The ratios are as follows: all PVP10, all PVP40, and PVP10:PVP40=1:5, 1:2, 2:1, and 5:1. The effect of changing PVP ratio is evident as the dominant PVP type is tested in both small and large majority manner. Samples containing only PVP40 or PVP10 were designated as “All-PVP40” and “All-PVP10”, respectively. The three runs were labeled A, B, and C.

CPSC(CPS Instruments Centrifuge) for SNPs.

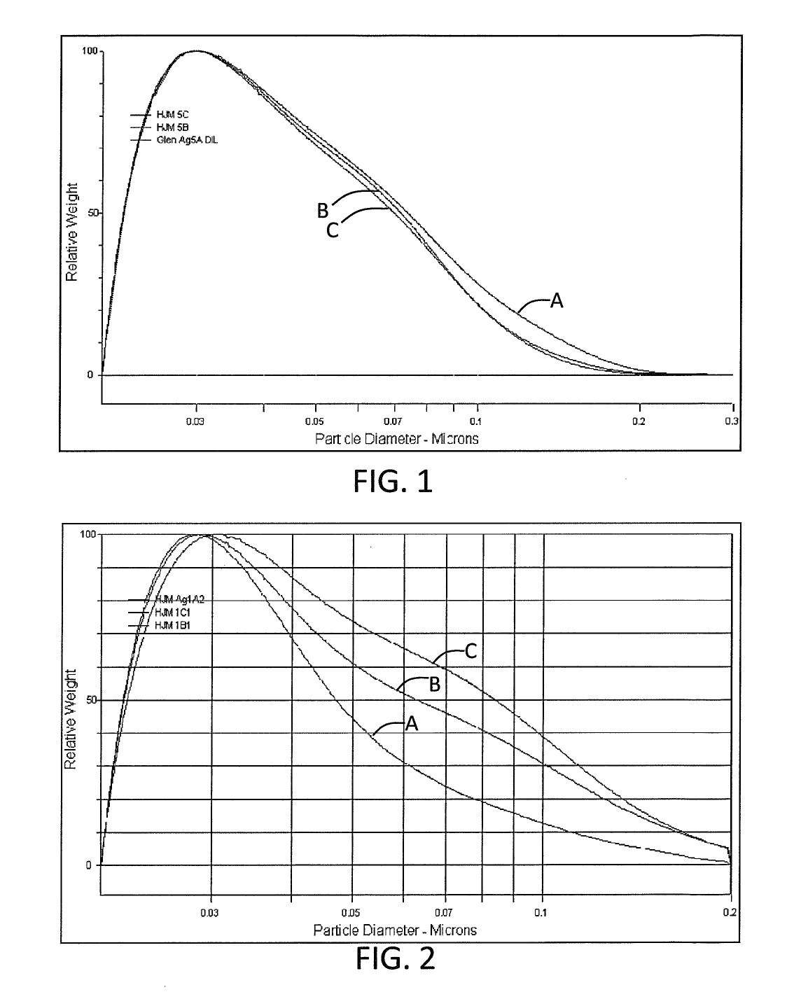

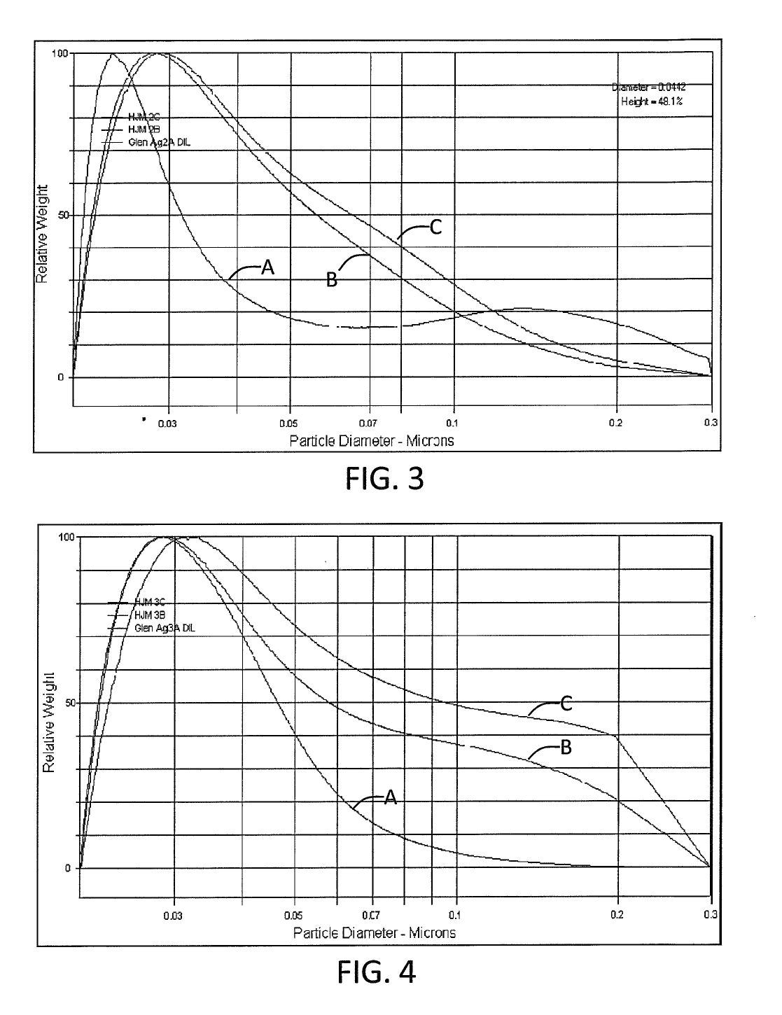

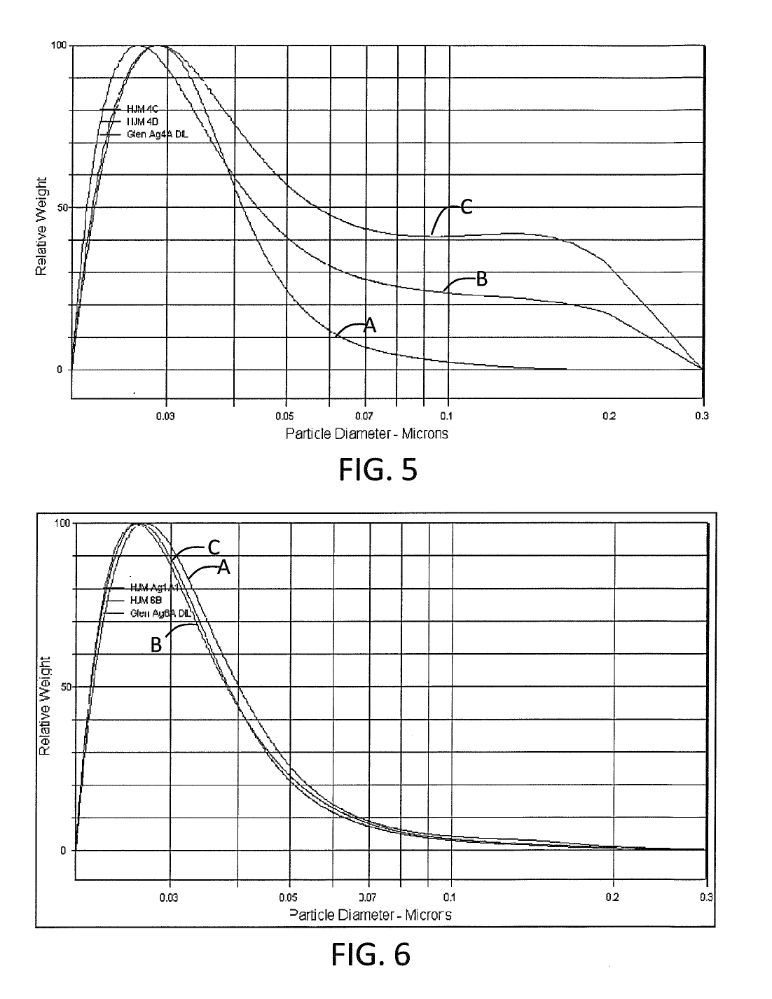

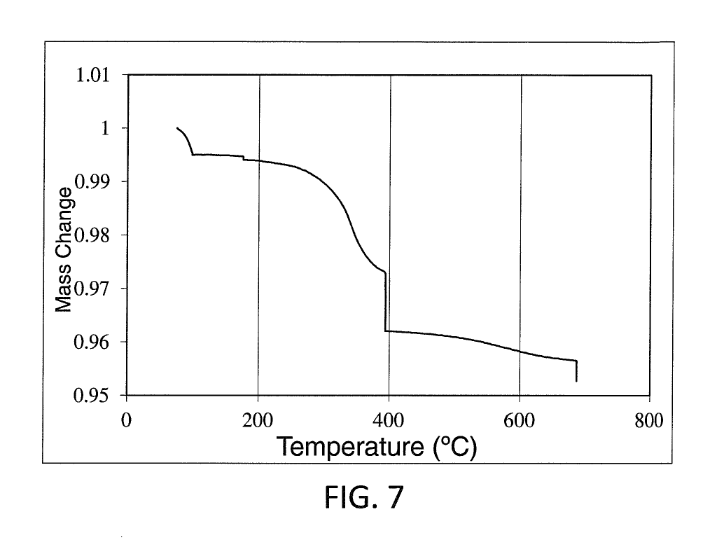

The CSPC results for the bimodal PVP MW systems are given in FIGS. 1-6. Samples are indicated by the letters A, B, and C.

The peak of the distribution was typically repeatable. The data showed that particles were typically smaller than 100 nm. The All-PVP10 samples gave only a small response above 100 nm, which agrees well with Nanotrac. This absence of particles in the intermediate size range gives pause as to how large particles can form in PVP10-only systems following washing/centrifugation. Large particles do not appear to be growing or agglomerating to an intermediate size range during reaction or centrifugation. CPSC also resolved the smaller particles that were interpreted as large in PVP40 and PVP55 samples in Nanotrac.

In CPSC, larger particles were not measured by Brownian motion and Doppler shift in this system. The individual particles in agglomerates were likely acted upon independently by the retardation effects of solution within the CPSC, with smaller effect from entanglement.

Particle sizes above 300 nm were not accounted for in these CPSC tests, but most graphs indicated that by 300 nm the particle response was already relatively small. In the bimodal systems, sample A was created about six months before the other two samples and was washed later. This may account for differences in CPSC output.

TGA (Thermal Gravimetric Analysis) of SNPs.

The effect of remaining PVP content on low-temperature sample resistivity has not been discussed in the literature. Mass loss of PVP versus temperature was recorded using a Perkin-Elmer TGA.

To measure the mass of PVP remaining in each sample, the temperature of each sample was first ramped at 20° C./min to 300° C. and then held for 120 min to remove excess water. The sample was then ramped at 20° C./min to 480° C. to obtain the total mass loss. Table 1 gives the mass loss percentage in each sample.

TABLE 1
TGA Results of Samples A, B and C

| | PVP40:PVP10 | | | | | |
|---|---|---|---|---|---|---|
| | AII-PVP40 | 5:1 | 2:1 | 1:2 | 1:5 | AII-PVP10 |
| Run A mass | 4.32 | 1.74 | 1.00 | 1.28 | 0.73 | 1.80 |
| loss (%) | | | | | | |
| Run B mass | 7.68 | 2.76 | 3.96 | 2.71 | 2.10 | 1.71 |
| loss (%) | | | | | | |
| Run C mass | 6.20 | 2.96 | 3.22 | 2.52 | 2.31 | 1.38 |
| loss (%) | | | | | | |

TEM Images of SNPs.

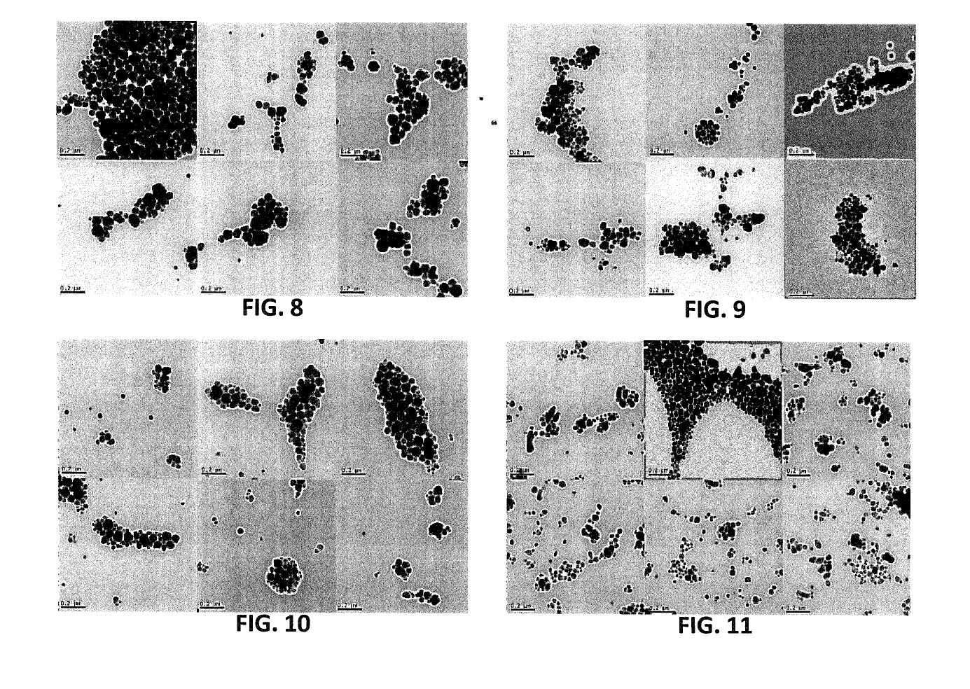

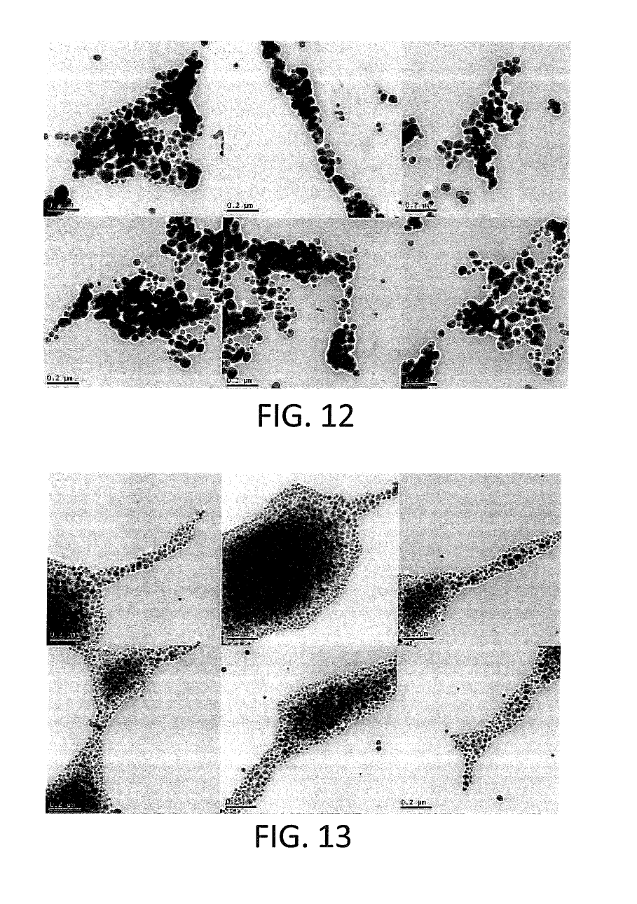

TEM (FIGS. 8-13) of SNPs are provided. These figures have scale bars of 0.2 microns as shown in the lower left corner of each graph. Little difference was found between samples in terms of size and morphology. They were also in general agreement with the data recorded by the CPSC. Particles exceeding 200 nm in size were absent in the TEM micrographs. Thus, both PVP10 and PVP40 are sufficiently protecting SNPs. In a few micrographs, some rather large particles could be found. These particles may have agglomerated during growth or compressed after centrifugation (causing PVP entanglement). SNPs, however, did not show evidence of coalescence: very few grain boundary lines were found in the TEM images.

Electrical Resistivity of SNPs.

Electrical resistivity measurements are the hallmark of most SNP studies. In the electronic device E-pill application, electrical resistance is of utmost importance. For example if the device is an antenna lower antenna resistance will lead to a higher quality factor, or Q, of the antenna, and thus greater radiating efficiency for use with biocompatible compounds.

The presence of PVP in a SNP film increases the film materials resistivity. Thus, the results of TGA analysis will be used in conjunction with electrical resistivity measurements. On a deeper level, the fact that SNPs are polymer-protected implies that the SNP surfaces are well-decorated via coordinative-bonded PVP, which prevents particle coalescence. Thus, unlike silver/polymer conductive composites where polymer and silver are loosely mixed with little to no coordinative bonding effect, PVP is physically attached to the surface of SNPs and is more difficult to move or remove. Thus, silver-to-silver contact is limited not only by a free-floating polymer, but by a bonded polymer.

A 4-point probe test system was the chosen method of testing sample sheet resistance. Samples were checked along multiple points on the sample surface. Film thickness was measured by a Brown and Sharpe Digit-Cal Plus digital caliper that spanned the width of the glass slide. Values of film thickness were taken about every 2 mm of the film and the average resistivity was calculated by multiplying the average film thickness by the average sheet resistance of each sample.

Some majority PVP10-synthesized samples showed one or two visible lines in SNP films where resistivity increased. These lines were thin, comprising less than about 5% of total film area. It is thought that these lines consisted mostly of PVP10 molecules that were not bound to SNPs. Drying effects due to the evaporation of water likely allowed them to form such line formations. Upon heat treatment, these areas showed improved conductivity, which was possibly due to evaporation of solvent and the subsequent compaction of SNPs and movement of loose PVP.

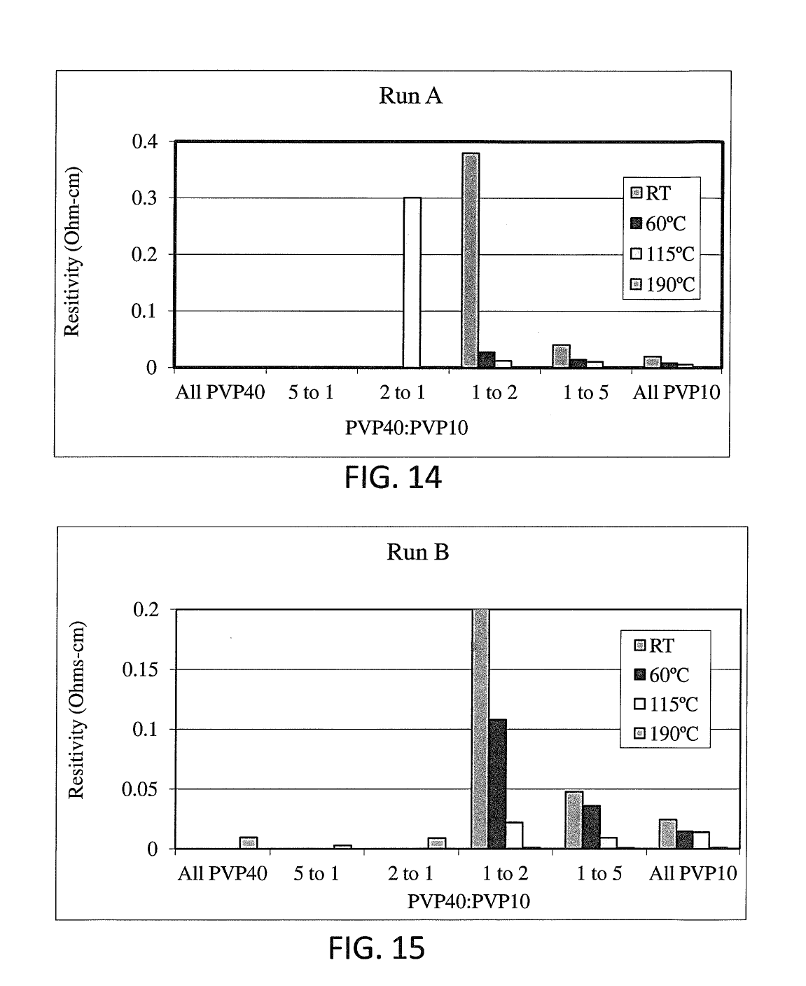

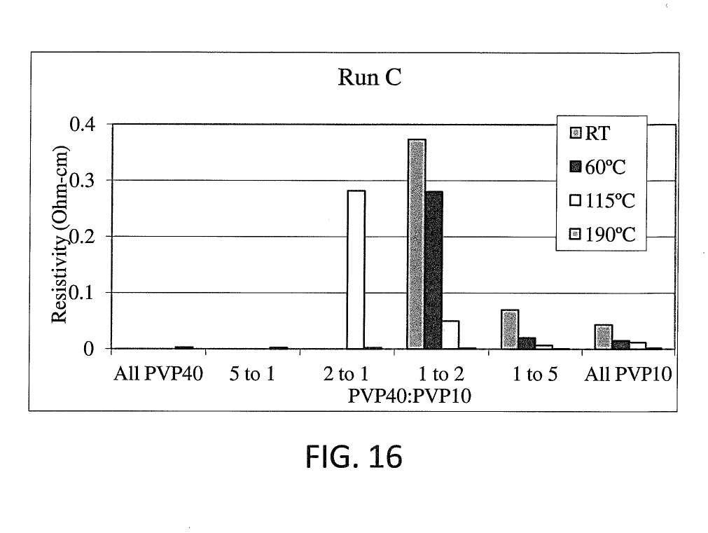

Tables 2-4 give the PVP mass percent remaining from TGA, the sheet resistance, and the electrical resistivity for each sample at different curing temperatures. FIG. 14 does not display 190° C. sintering data because the resistivity is extremely low. FIGS. 14-16 give the resistivity vs. PVP40:PVP10 for each temperature. Sintering appears to be occurring at 190° C. (displayed in SEM images in a forthcoming section), which accounts for the precipitous drop in resistivity in some samples.

TABLE 2
Resistivity vs. Temperature and PVP Content for Run A.

| | PVP40:PVP10 | | | | | |
|---|---|---|---|---|---|---|
| | AII-PVP40 | 5 to 1 | 2 to 1 | 1 to 2 | 1 to 5 | AII-PVP10 |
| Mass loss (%) | 4.32 | 1.74 | 1.00 | 1.28 | 0.73 | 1.80 |
| | Resistivity at given temperature (Ω-cm) | | | | | |
| Room temperature | | | | 3.8(10)⁻² | 4.0(10)⁻³ | 2.0(10)⁻³ |
| 60° C. | | | | 2.7(10)⁻³ | 1.4(10)⁻³ | 8.2(10)⁻⁴ |
| 115° C. | | | 3.0(10)⁻² | 1.2(10)⁻³ | 1.1(10)⁻³ | 5.4(10)⁻⁴ |
| 190° C. | 4.4(10)⁻⁴ | 1.6(10)⁻⁴ | 7.4(10)⁻⁵ | 7.7(10)⁻⁵ | 9.1(10)⁻⁵ | 7.5(10)⁻⁵ |

TABLE 3
Resistivity vs. Temperature and PVP Content for Run B.

| | PVP40:PVP10 | | | | | |
|---|---|---|---|---|---|---|
| | AII-PVP40 | 5 to 1 | 2 to 1 | 1 to 2 | 1 to 5 | AII-PVP10 |
| Mass loss (%) | 7.88 | 2.76 | 3.96 | 2.71 | 2.10 | 1.71 |
| | Resistivity at given temperature (Ω-cm) | | | | | |
| Room temperature | | | | 5.7(10)⁻¹ | 4.8(10)⁻³ | 2.5(10)⁻³ |
| 60° C. | | | | 1.1(10)⁻² | 3.6(10)⁻³ | 1.5(10)⁻³ |
| 115° C. | | | | 2.2(10)⁻³ | 9.3(10)⁻⁴ | 1.4(10)⁻³ |
| 190° C. | 9.5(10)⁻⁴ | 2.8(10)⁻⁴ | 8.9(10)⁻⁴ | 9.7(10)⁻⁵ | 7.4(10)⁻⁵ | 1.0(10)⁻⁴ |

TABLE 4
Resistivity vs. Temperature and PVP Content for Run C.

| | PVP40:PVP10 | | | | | |
|---|---|---|---|---|---|---|
| | AII-PVP40 | 5 to 1 | 2 to 1 | 1 to 2 | 1 to 5 | AII-PVP10 |
| Mass loss (%) | 6.20 | 2.96 | 3.22 | 2.52 | 2.31 | 1.38 |
| | Resistivity at given temperature (Ω-cm) | | | | | |
| Room temperature | | | | 3.7(10)⁻² | 7.0(10)⁻³ | 4.4(10)⁻³ |
| 60° C. | | | | 2.8(10)⁻² | 2.0(10)⁻³ | 1.6(10)⁻³ |
| 115° C. | | | 2.8(10)⁻² | 5.0(10)⁻³ | 6.8(10)⁻⁴ | 1.2(10)⁻³ |
| 190° C. | 2.9(10)⁻⁴ | 2.3(10)⁻⁴ | 2.3(10)⁻⁴ | 1.8(10)⁻⁴ | 8.5(10)⁻⁵ | 1.8(10)⁻⁴ |

A notable feature of run B is the difference in resistivity between samples of similar PVP content, which also occurred in run A. In sample B, two samples are very close in final PVP content: the PVP10:PVP40=1:5 and 2:1 These samples contained a PVP mass content of 2.76% and 2.71%, respectively. Yet, the conductivities are extremely dissimilar. Placing a Fluke digital multimeter across a thin film of the 1:5 sample of 2 cm×2 cm dimension gives a reading in the MC) range at temperatures of 115° C. and below. The same measurement on a similar area on the 1:2 sample gives a resistance reading of a few Ohms. Simple PVP mass difference cannot explain this property. The arrangement of different MWs of PVP on the surface of SNPs is a likely cause of the large difference.

Dearden et al. (2005) obtained a resistivity of approximately 1 Ω-cm at 125° C. for their SNPs that were described as being of low curing temperature. This present study showed lower resistivity by one to three orders of magnitude at room temperature. All the samples synthesized by a of majority PVP10 in Run A fulfilled this condition at room temperature with the exception of run C, sample PVP40:PVP10=1:2 (it had a higher PVP content remaining than any other PVP40:PVP=1:2 samples).

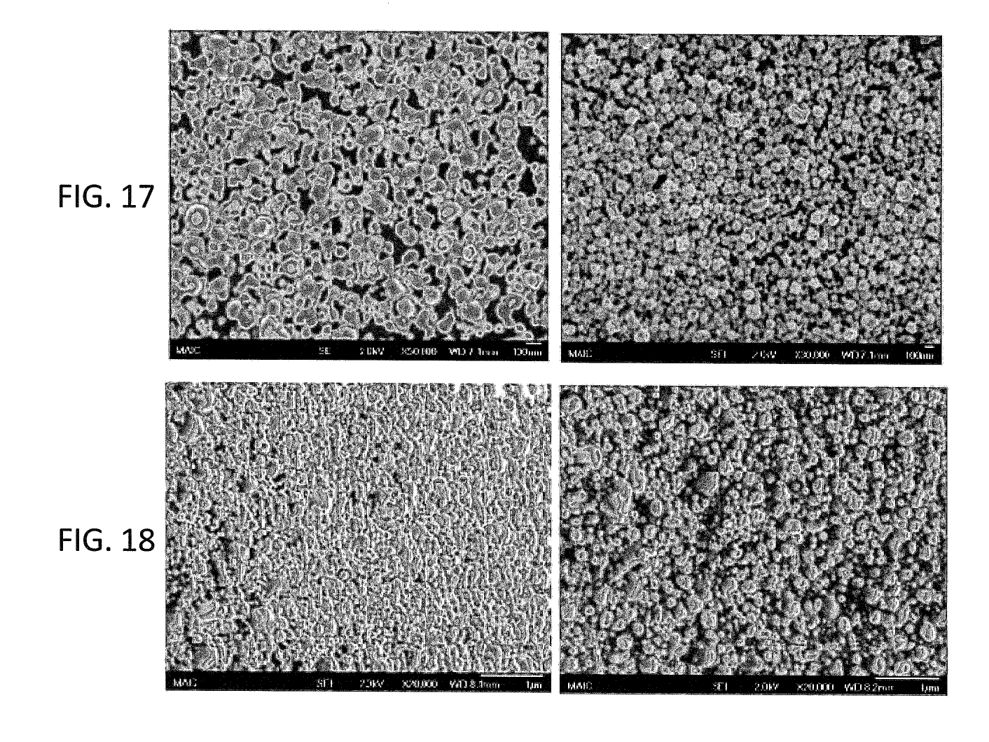

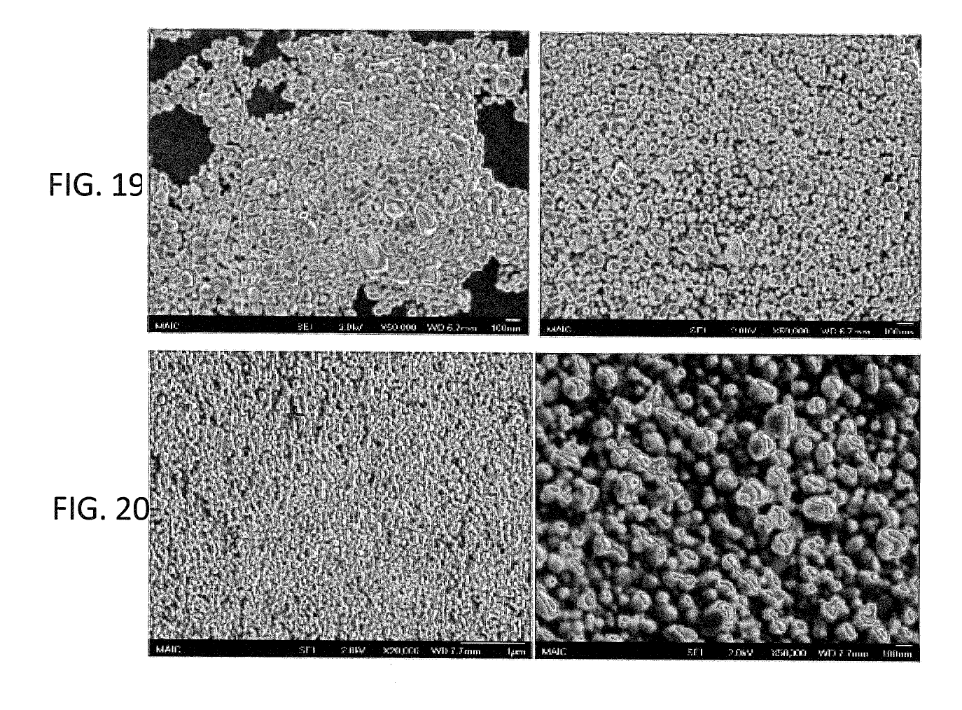

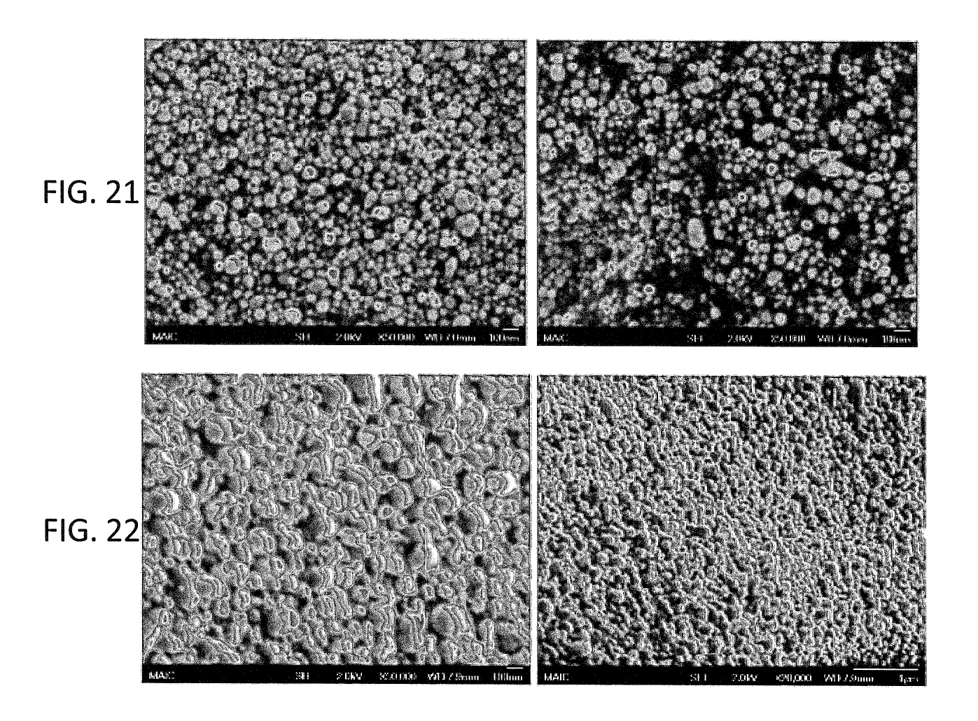

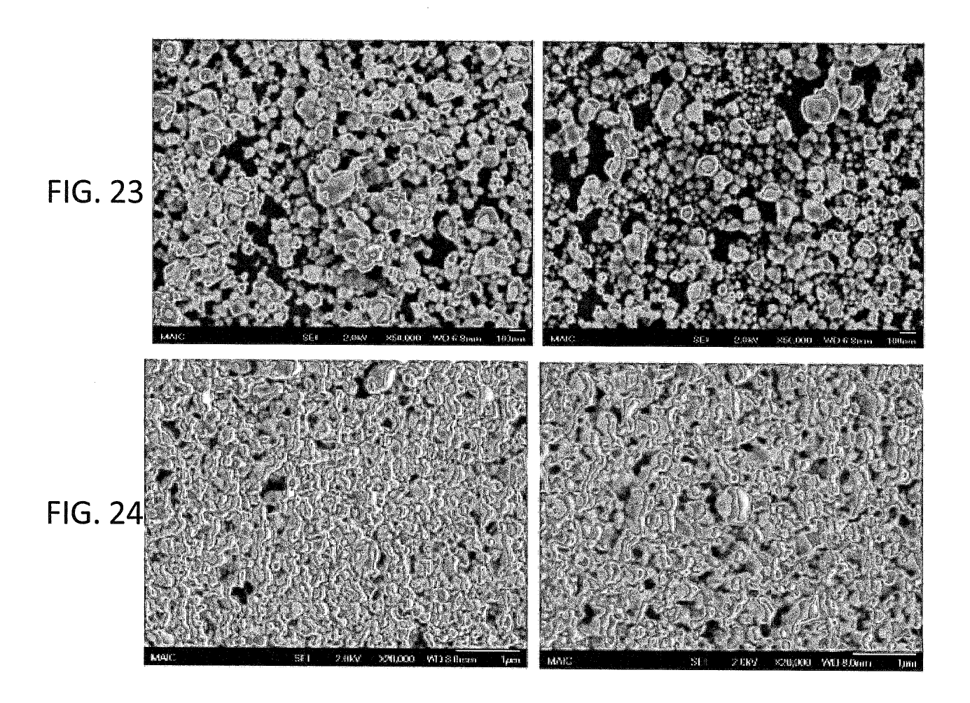

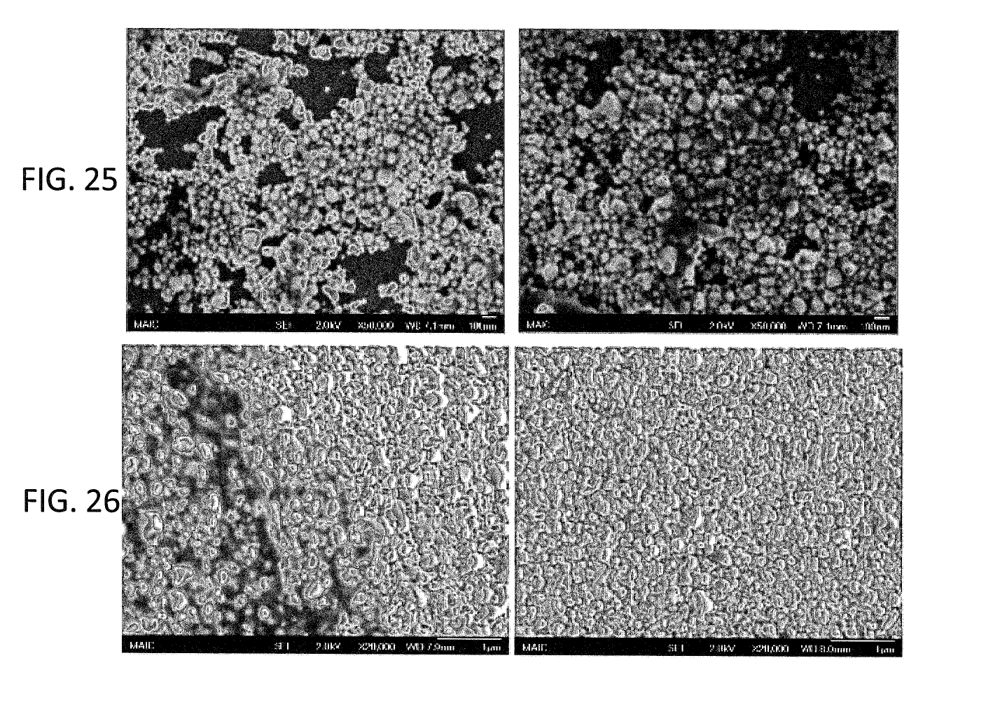

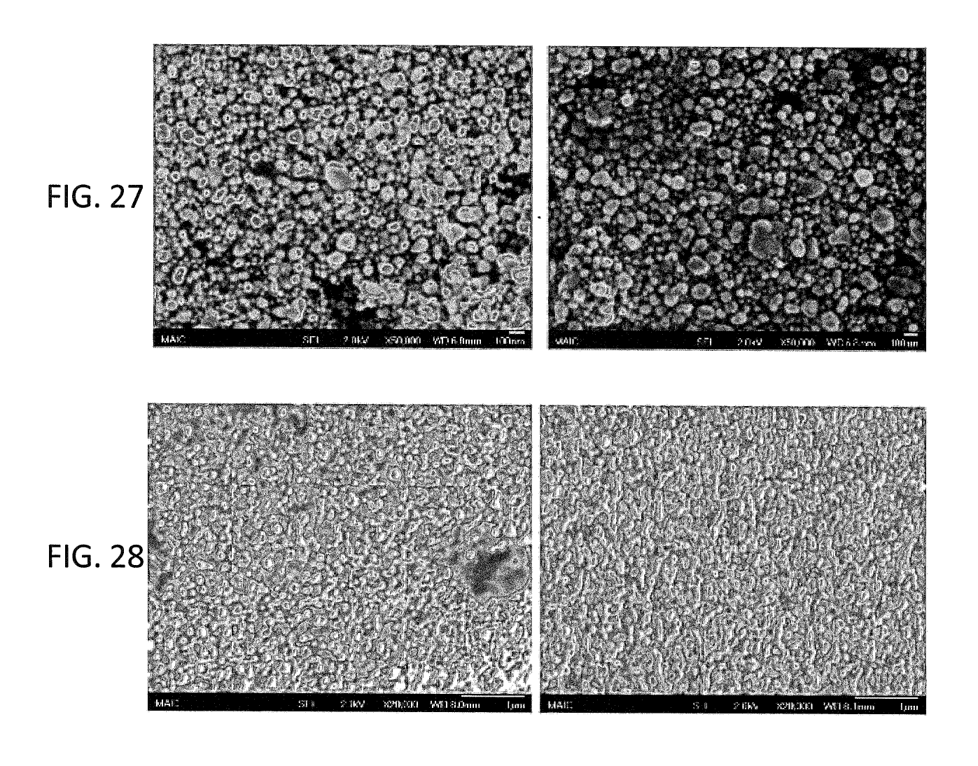

The present invention's bimodal MW PVP SNP protection may allow for prototyping of E-pill antennas without the need for thermal treatments that may cause gelatin capsules to degrade or deform. SEM Images of Sintered SNPs. FIGS. 17-28 show SEM micrographs of SEMs sintered at 160° C. and 190° C. At 160° C., no extensive particle sintering was observed. Particle sintering thus does not explain the drop in resistivity of these samples, so SNP resistivity must be explained by a model like that shown in FIG. 18. At 190° C., particle sintering could be observed, which explains the marked drop in resistivity across all samples.

For all of the SEM images in this section, an atmospheric plasma flow was applied to remove any surface polymer that might cause focus problems due to polymer outgassing.

Summary of Bimodal PVP MW SNPs.

Bimodal MW PVP-protected SNPs were created with sizes on the order of tens of nanometers and averaged about 2% by mass PVP. As the fraction of PVP increased towards PVP10 in a bimodal PVP MW system, the electrical resistivity decreased to a point where SNP inks could be useful in printing conductive silver traces at low temperatures.

### Example 3

### Characterization of SNP Films

Current-Voltage Analysis of SNP Thin Films.

Because PVP is an electrical insulator, PVP between SNPs creates a potential barrier that impedes the flow of electrical charge through a material. One possible mechanism for the difference in resistivity between majority PVP10-synthesized SNPs and majority PVP40-synthesized SNPs is how each respective PVP affects the ability for electrons to tunnel through a potential barrier or overcome a relatively small potential barrier (with a sufficient amount of applied heat or voltage). Previous literature studies identified that contact between a metal and a polymer creates a “triangular” potential barrier (Koehler and Hummelgen, 1997). For small potential barriers at high temperatures, thermionic emission may allow a large number of charge carriers to overcome the potential barrier. At low temperatures, charge carriers must tunnel through the potential barrier. Charge carriers tunnel from the metal to the lowest unoccupied molecular orbital or the highest occupied molecular orbital (which is the band gap energy in organic semiconductor materials). The nanoparticle separation distance between SNPs caused by PVP, which was approximately 2 nm, may be thin enough to allow electrons to tunnel from one SNP into another.

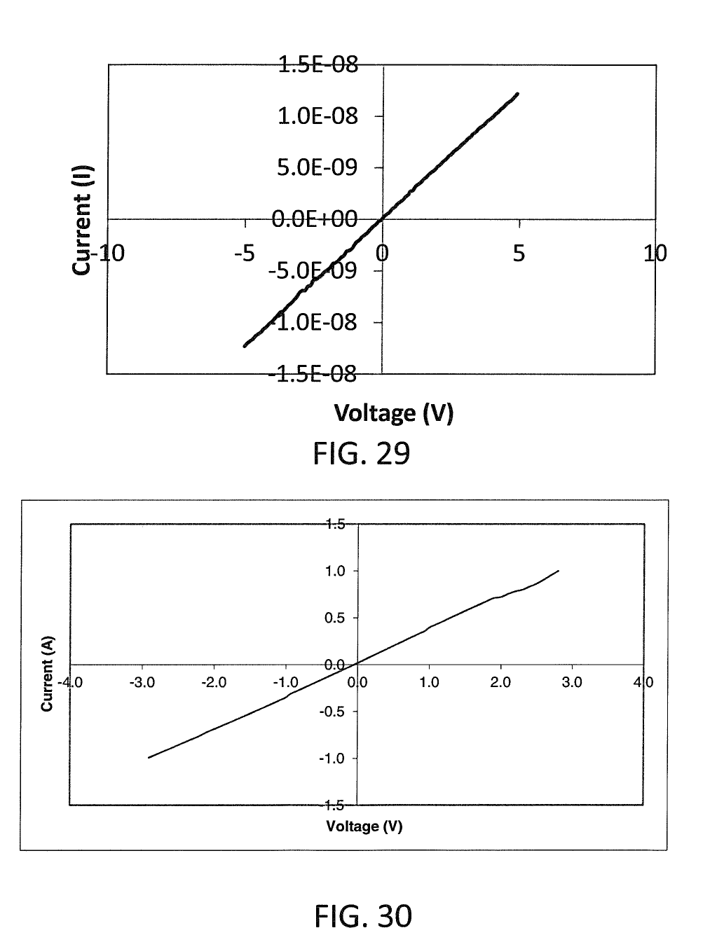

The literature reported a gradually increasing (non-linear) current with respect to voltage for poly(4,7-benzothiophene-vinylene)/aluminum multi-layer thin films (Berton et al., 1998), with charge carrier injection due to tunneling. Such a thin film is analogous to the system presented here. In FIG. 29, a SNP sample synthesized using PVP40:PVP10=2:1 is shown with linear I-V behavior. In FIG. 30, the I-V characteristics for a SNP sample synthesized using PVP40:PVP10=1:5 is shown producing a much larger current compared to majority PVP40-synthesized samples (this behavior was also found for the All-PVP10 sample). PVP40:PVP10=1:5 and All-PVP10 samples showed slight increases in the magnitude of the current/voltage slope starting at approximately 0.3 V when films were heated to 115° C. In contrast, every majority PVP40-synthesized SNP film as well as SNPs synthesized with PVP40:PVP10=1:2 exhibited essentially linear/Ohmic characteristics at temperatures ranging between 60° C. and 115° C. These samples generally exhibited relatively high electrical resistance. Table 5 gives the current at 115° C. at a series of voltages for each bimodal PVP system tested in this work.

TABLE 5
Current at various voltages for SNP thin films at 115° C.

| | PVP40:PVP10 | | | | | |
|---|---|---|---|---|---|---|
| | AII-PVP40 | 5 to 1 | 2 to 1 | 1 to 2 | 1 to 5 | AII-PVP10 |
| Voltage (V) | Current (A) | | | | | |
| −1 | −6.8(10)⁻¹⁰ | −1.9(10)⁻⁹ | −2.4(10)⁻⁹ | −1.2(10)⁻³ | −3.0(10)⁻¹ | −2.6(10)⁻¹ |
| −0.5 | −3.6(10)⁻¹⁰ | −6.3(10)⁻¹⁰ | −1.3(10)⁻⁹ | −5.8(10)⁻⁴ | −1.5(10)⁻¹ | −1.3(10)⁻¹ |
| 0.5 | 5.3(10)⁻¹⁰ | 1.1(10)⁻⁹ | 1.5(10)⁻⁹ | 7.0(10)⁻⁴ | 1.7(10)⁻¹ | 1.5(10)⁻¹ |
| 1 | 8.8(10)⁻¹⁰ | 2.2(10)⁻⁹ | 2.7(10)⁻⁹ | 1.4(10)⁻³ | 3.6(10)⁻¹ | 2.7(10)⁻¹ |

The polymer-metal interface is on both sides of an SNP; therefore, as current is passed through a SNP film, the charge carriers encounter a series of potential barriers (Magonov et al., 1997). For current to travel from one probe to another probe at low temperatures, it must overcome these barriers via tunneling. The Fowler-Nordheim expression states that current (in light of these potential barriers) is proportional to the square of the applied voltage for polymer-metal interfaces. However, a square dependence is not observed in the samples investigated in this study. Instead, for the SNP film synthesized using PVP40:PVP10=1:5 (FIG. 30), there appears to be only a slight change in slope in the I-V graph (FIG. 30) at 0.3 V. This may indicate that elevated temperature (115° C.) and applied voltage cause charge carriers in the SNP film to overcome potential barriers caused by the PVP between SNPs, therefore contributing to the measured current.

Another contribution of current, which is due to exposed silver faces on majority PVP10-synthesized SNPs, is discussed below. Those findings will better explain the large difference in resistivity between majority PVP10- and majority PVP40-synthesized SNP films. The majority of electrical charge in SNP films is most likely not tunneling through or overcoming potential barriers, but instead flowing through regions of exposed silver.

Atomic Force Microscopy of SNPs. The following three observations from the resistivity experiments on bimodal-PVP-synthesized SNPs can be made. (1) The electrical resistivity was much smaller in majority PVP10-synthesized SNPs than majority PVP40-synthesized SNPs at temperatures below that at which SNPs began to sinter. (2) No correlation was found between the amount of PVP remaining (as recorded by TGA) in each sample and the electrical resistivity of each sample. (3) No correlation was found between SNP size (or size distributions) and electrical resistivity, as shown in the multiple TEM and SEM micrographs as well as through centrifugal size measurement techniques. These techniques showed, both visually and quantitatively, that size distributions of SNPs all followed similar patterns and ranges.

From these observations, a hypothesis was drawn that perhaps the quality of the PVP decoration on the surface of SNPs could help explain the difference in resistance in I-V measurements as well as the 4-point probe tests above. To identify the quality of PVP decoration, atomic force microscopy (AFM) was chosen to detail the surface hardness of the nanoparticles. By using AFM phase-detection mode, which is sensitive to changes in surface elasticity and surface stiffness by monitoring the oscillation phase shift associated with tip-sample repulsive interactions (Magonov et al., 1997), one can distinguish between soft, PVP-decorated areas on SNPs and any possible stiff, silver-exposed areas. Therefore, two thin films—one each of PVP10-synthesized SNPs and PVP40-synthesized SNPs were created.

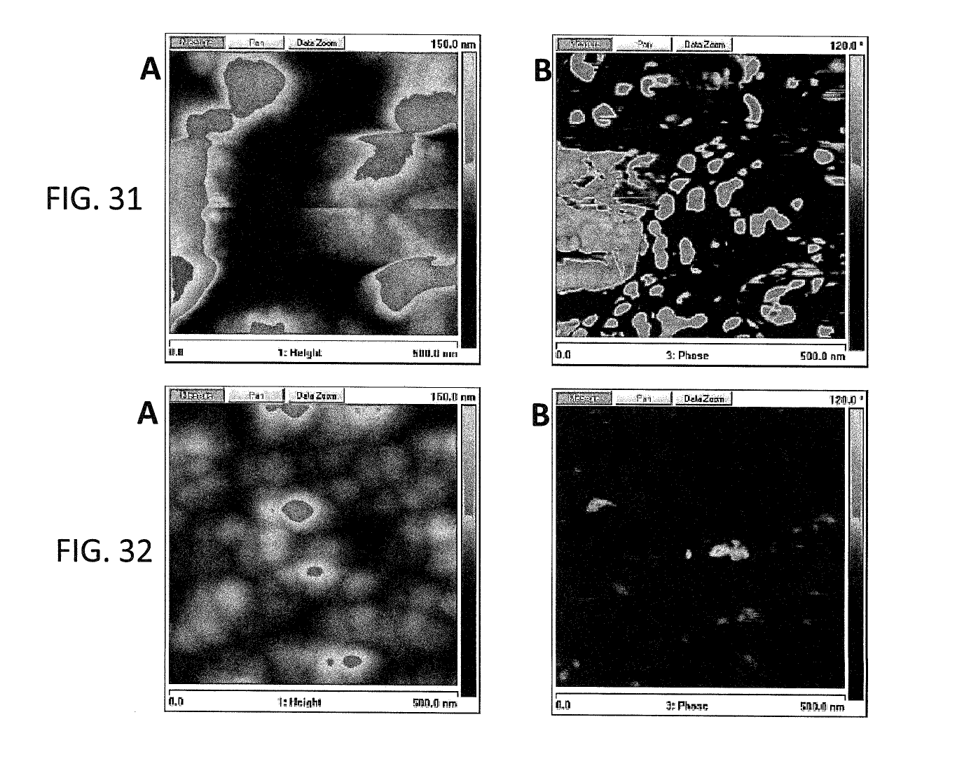

In FIGS. 31 and 32, two sets of AFM images are shown and in each set the same area was sampled. The first image in each set shows the surface topography of the SNP film and the second image shows the phase shift of the AFM tip as it interacts with the surface of SNPs. Topography mode records the height of the SNP film. In phase-shift AFM imaging, stiffer surfaces are distinguished by a large phase shift (bright yellow areas) with abrupt edges. Stiffer surfaces alter the effective spring constant of the AFM cantilever (Magonov et al., 1997) and cause a greater phase shift. Notice that the PVP10-synthesized SNPs (FIG. 31) display a multitude of areas that are very stiff. This is evidence that PVP is absent or in small or thin amounts in these areas (in other words, the AFM probe is tapping on silver rather than on PVP). PVP40-synthesized SNPs exhibit this effect to a much smaller degree, indicating that PVP decorates the SNP surface more consistently. Yellow areas in the phase-shift image of PVP40-synthesized SNPs (FIG. 32) do not show abrupt changes in brightness; therefore, these lighter areas are likely to be only thinly decorated with PVP rather than fully exposed.

Long PVP chains bind to multiple sites on a metal nanoparticle. Upon drying, the PVP chain constricts (solvent is removed) and the polymer end-to-end distance is believed to shrink. The number of bonding sites of the PVP chain restricts the degree to which the distance decreases. Since PVP40 is a longer chain than PVP10, it will likely have a larger number of bonding sites per molecule and the shrinkage is mitigated. PVP10 will have fewer bonding sites and polymer is freer to shrink upon removal of solvent, leaving exposed areas of silver.

Thus, AFM images show that PVP10 is not decorating SNP surfaces as consistently as is PVP40. This evidence can explain why resistivity is much lower in majority PVP10-synthesized SNPs than majority PVP40-synthesized SNPs: exposed silver on one majority PVP10-synthesized SNP can contact the exposed silver on another majority PVP10-synthesized SNP and this electrical “contact resistance” will be much smaller than electrical resistance due to polymer on the surface of SNPs (as in the case of PVP40).

In summary, the large difference in electrical resistivity between majority PVP10-synthesized SNPs and majority PVP40-synthesized SNPs at temperatures below that which SNPs sinter can be attributed to the degree of PVP surface decoration.

Summary of Electrical Resistivity of SNPs Cured at Temperatures Below their Sintering Temperature.

Based on the observations and data presented herein, it is believed that the lower resistivity of majority PVP10-synthesized SNPs as compared to majority PVP40-synthesized SNPs is caused by one major reason: PVP on the surface of SNPs is decreasing in end-to-end distance as water evaporates from the system, The reduction in PVP size may further open any areas of the SNP surface that may have not been well-protected during SNP synthesis. This may allow for silver-to-silver contact between SNPs. To that effect, upon drying, the end-to-end distance of PVP10 may be decreasing in a manner that differs from PVP40. This is sensible depending on how PVP40 binds compared to PVP10: one expects that longer PVP chains are more likely to have multiple binding points on a given SNP than a shorter chain. Thus, as water evaporates from PVP40, its multiple bonding points may prevent the molecule from shrinking along the surface of a SNP as much as PVP10 molecules can. Furthermore, the added chain length of PVP40 in the form of PVP tails (Hirai et al., 2001) might create a significant enough separation distance between SNPs so to further impede silver-to-silver contact between two SNPs.

Two additional mechanisms may also contribute to the decreased resistivity in majority PVP10-synthesized SNPs. As discussed earlier in this study on PVP40 gels as well as in agglomerations found by Nanotrac, PVP40 that is bonded on the surface of SNPs may entangle unbound PVP40 molecules from solution. This may have added another PVP layer that further increased electrical resistivity. This entanglement is due to the degree of PVP polymerization, as described previously in this work. Upon application of heat to SNPs, thermal agitation may affect long and short PVP chains differently. Because SNPs are spherical spatial voids exist in any SNP film. Loose (non-bonded) PVP40 molecules that are entangled may be harder to move compared to loose PVP10 molecules (which are more difficult to entangle), preventing the exposure of open silver surfaces upon drying and curing. These entangled PVP40 molecules are thus immobilized whereas PVP10 molecules can move into spatial voids.

### Example 4

### Printing of SNPs

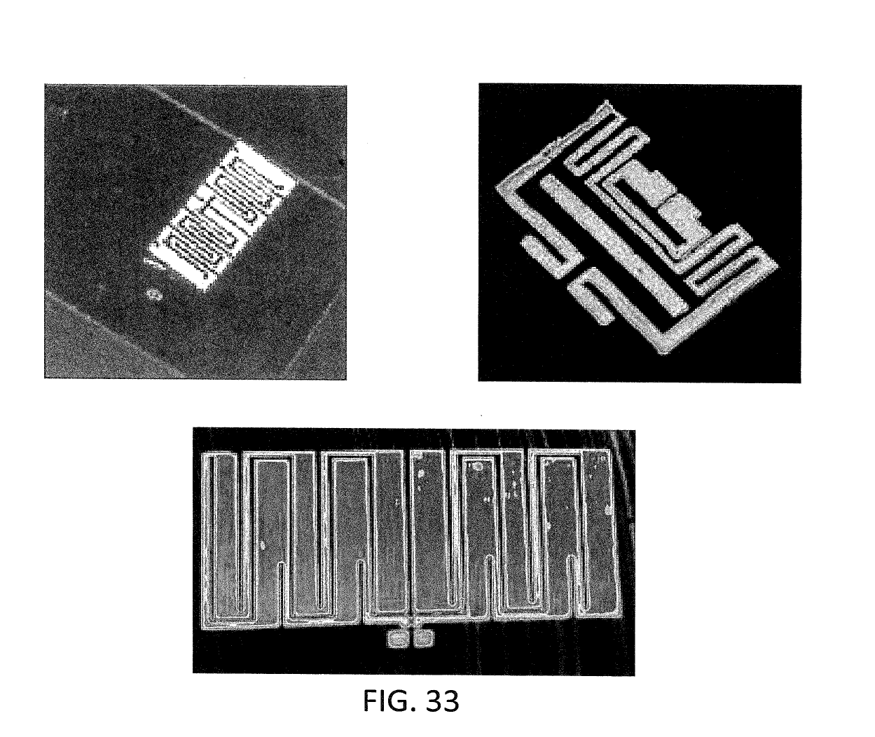

The SNPs of this invention are capable of being formed into usable inks for manufacturing electronic devices. The system tacked in 3-10 s and was usable in a pad printing process (allowed for the transfer of an image to the pad from a cliché). A picture of silver antennas pad-printed onto a glass slide and polyimide are shown in FIG. 33 for demonstration purposes of the printability of bimodal MW SNP inks. The formulation for the antennas was PVP40:PVP10=1:1.

### Example 5

### Nanoparticle Ink Properties

The methodology of this invention was able to show control over particle size and excellent conductivity both below and above the sintering temperature of the SNPs.

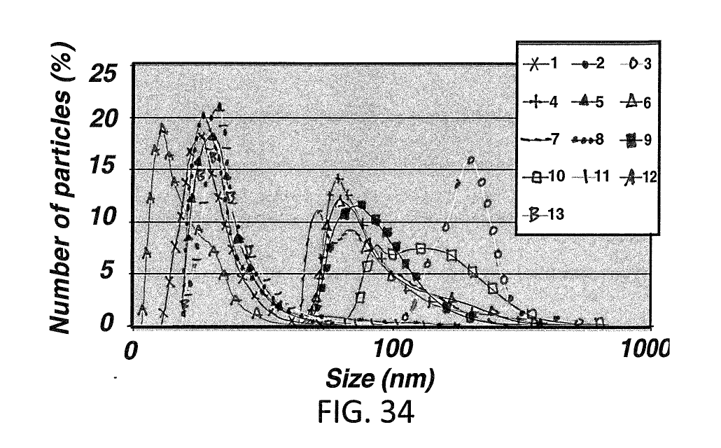

The electrical resistance of the silver nanoparticle ink is of utmost importance as lower antenna resistance leads to high quality factor and thus greater radiation efficiency. Particle size measurements are also important as it provides general ideas as to the reaction extent: larger particles with odd morphology may indicate that particles coalesced rather than remained separate; very small particles would indicate that growth rates did not exceed nucleation rates. As shown in FIG. 34 below, the particle size of the ink is affected by the molecular weight and amount of the PVP used. The resulting particle sizes for PVPs with different molecular weight and amount are characterized by a Microtrac Nanotrac, model NPA150, and it is shown that using PVP with lower molecular weight results in smaller particle size, despite adjustments in NaOH concentration. For PVP10, nearly all SNPs or agglomerations remained at a size range of 10 to 80 nm. For PVP of higher MW, nanoparticles covered a range from around 40 nm to about half a micron, with size distribution peaks most prominent near 80 nm for the majority of higher MW PVP-protected systems. These results indicate very good conductivity compared to the literature (Lee et al., 2005).

To better resolve the effect of PVP MW for practical results that can be applied to conductive ink technology to produce the highest conductivity at a given temperature, three different runs of binary PVP MW were prepared, each at different PVP10 to PVP40 mass ratios. The major objective of this series of experiments was to determine what type of PVP or PVP combination is best to create inks formulations for capsule antennas. The binary PVP MW ratios are all PVP10, all PVP40, and PVP10:PVP40=1:5, 1:2, 2:1, and 5:1.

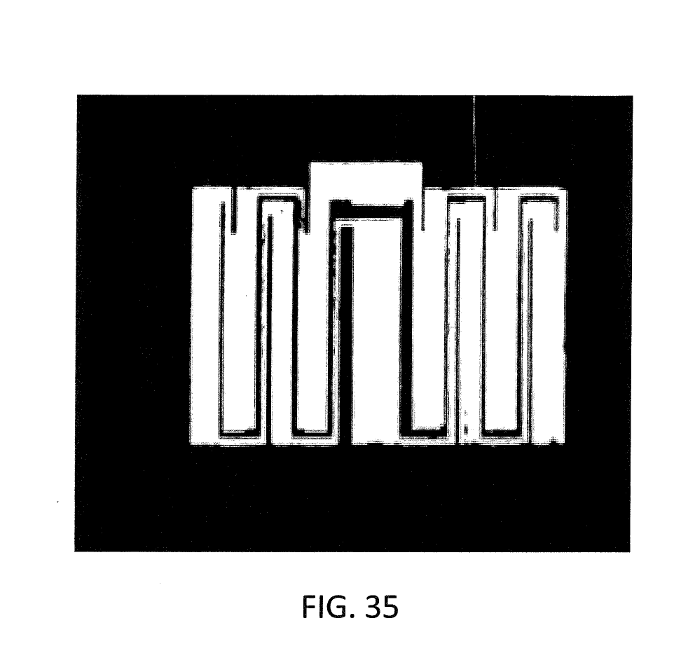

From these results, there is provided a suitable nanoparticle system that can be combined with an organic ethylcellulose binder to create silver inks that can be used to print silver electronic device patterns. The binder may include a-terpineol and ethylcellulose as well as a propylene glycol viscosity modifier. FIG. 35 gives an example of an antenna pattern that can be printed with the inks. In other embodiments, the ink is printed with no binder.

### Example 6

### Nanoparticle Ink Biocompatibility

The section below discusses the measurement of silver release into artificial gastric juices using inductively couple plasma-atomic absorption spectroscopy. Once printed on a suitable biocompatible substrate, the biocompatible substrate may be swallowed by a subject or otherwise introduced into the subject. The purpose of Inductively Coupled Plasma-Atomic Emission Spectroscopy (ICP-AES) analysis is to quantify the amount of silver likely to be produced from ingestion of the biocompatible antenna.

ICP-AES requires samples to be in solution and operates based on atomic emission of [silver] atoms that reach the ICP argon plasma. The atoms are ionized by the argon plasma and thus the electrons are excited to a state higher than the ground state. As the electrons return to the ground state, a photonic emission occurs which is characteristic of what atoms might be pumped through the plasma. Dual monochromators give a detection limit of less than 1 part per million. (For silver in the Particle Engineering Research Center's ICP, the emission is high enough that 0.01 ppm, or 10 parts per billion, can be identified).

ICP-AES provides an output of the amount of silver released into solution following dissolution in artificial gastric juices. This output is measured in parts per million and is calibrated against known standards.

The main objective of ICP-AES analysis is to see how much silver is released into the artificial gastric juice as silver ion. As described by Drake and Hazelwood (2005) and elsewhere, the likely source of the only highly manifest side-effect of silver ingestion, argyria, is soluble silver salts, including silver nitrate, silver sulphadiazine, silver acetate, etc. Insoluble silver compounds and metallic silver are thought to pass through the body with no ill side effects. Therefore, when explaining the biocompatibility of silver metal, the focus should be on the silver that is released into solution as silver ion. ICP-AES checks explicitly for ions in solution, silver included, and thus the ICP-AES analysis should give us a good idea of the amount of silver that is likely to be absorbed by the body.

Our silver antennas were transfer printed to Eudragit FS30D. Eudragit FS30D is a biodegradable substrate that can be used as the substrate for all future E-pills. It dissolves at pH 7 (colonic area). Because of high pH dissolution, antennas will be able to remain physically intact in the stomach for prolonged detection possibilities.

TABLE 6
Silver release from 20 mL solution

| Material | Nano | 0.1 ppm | 1 ppm | 10 ppm | AGJ 20 mL | AGIJ 20 mL |
|---|---|---|---|---|---|---|
| Average (ppm) | 0 | 0.192 | 1.04 | 10.25 | 0.1162 | 1.083 |
| Total silver (mg) | | | | | 0.002324 | 0.02166 |
| Total silver (ug) | | | | | 2.324 | 21.66 |

Biocompatibty Experiment 1.

In our first experiment, antennas were placed in 20 mL AGJ and AGIJ. Table 6 and FIG. 36 report the results. In Table 6, Nano stands for Nanopure water. Each sample designated by ‘ppm’ stands for each calibration standard of 0.1, 1, and 10 ppm. Table 6 gives the average release. FIG. 36 gives a reading for each of 5 runs.

From these data, one can see that the Nanopure, AGJ, and AGIJ solutions read properly—showing no sign of silver. The calibration standards are mostly correct, except that the 0.1 ppm reads nearly double its intended concentration. The more dilutions of the calibration standard, the less precise it will be, and thus some experimental error is introduced.

From these measurements, the average concentration of Ag in AGJ is about 0.12 ppm. In 20 mL H₂O, this translates to approximately 2.4 μg of silver. The AGIJ solutions contained about 22 μg silver. From this we see that a very small amount of silver is released into the gastric juices.

Biocompatibty Experiment 2.

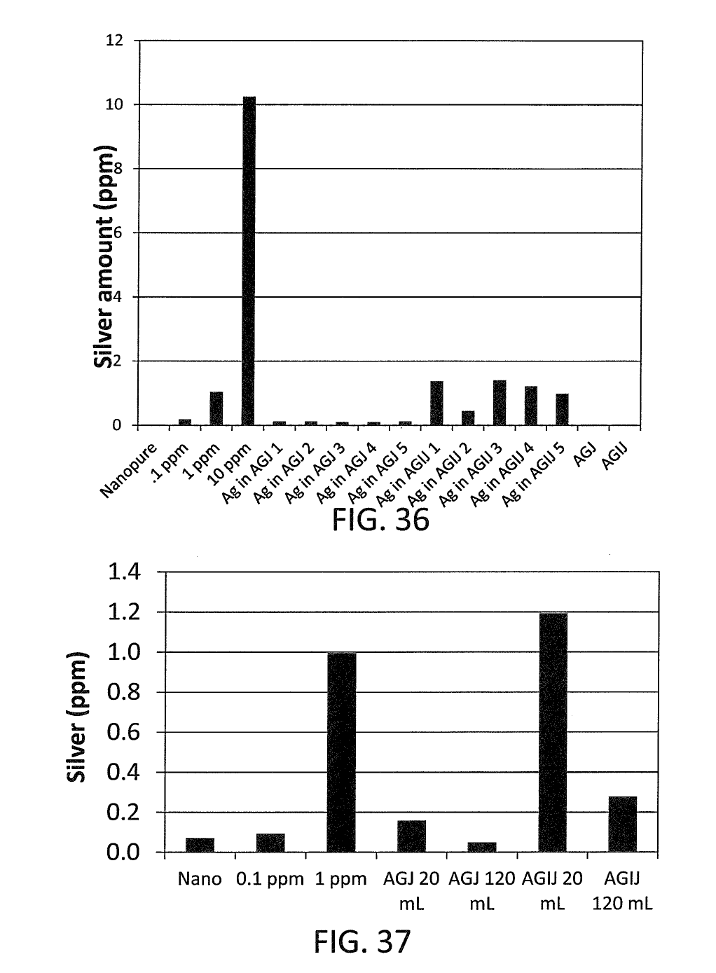

In our second experiment, antennas were again placed in 20 mL AGJ and AGIJ and 120 mL of gastric solution was also used to better identify the amount of total silver released. Table 7 and FIG. 37 report the results. The same nomenclature as for the first experiment is used for labeling.

TABLE 7
Silver release in 20 and 120 mL solutions of AGJ and AGIJ.

| | | | | | AGJ | AGJ | AGIJ | AGIJ |
|---|---|---|---|---|---|---|---|---|
| Material | Nano | 0.1 ppm | 1 ppm | 10 ppm | 20 mL | 120 L | 20 L | 120 mL |
| Average (ppm) | 0.071 | 0.094 | 0.995 | 10.004 | 0.158 | 0.048 | 1.194 | 0.277 |
| Total silver (mg) | | | | | 0.003155 | 0.005784 | 0.02388 | 0.033216 |
| Total silver (ug) | | | | | 3.155 | 5.784 | 23.88 | 33.216 |

From these measurements, the average concentration of Ag in AGJ 20 mL is about 0.15 ppm. In 20 mL H₂O, this translates to approximately 3.2 μg of silver, which is similar to the first experiment. The AGIJ solutions contained about 24 μg silver. Again, a very small amount of silver is released into the gastric juices.

In the AGIJ solutions, an antenna could be seen at the bottom of the vessel, intact and in one piece (or two pieces). This indicates that the antenna was not easily and entirely dissolvable.

From these biocompatibility studies, we have strong data to confirm the literature report by Drake and Hazelwood (2005) that silver is soluble in a limited fashion only. Because the pad printing technique tends to print stray silver nanoparticles that were not deposited solely in the grooves of cliché, these loose particles may add to the final silver concentration. Thus, this test ought to be viewed as a worst-case scenario.

The below examples illustrates further embodiments of silver nanoparticles, silver nanoparticles inks, and biocompatible substrates having the silver nanoparticle inks printered thereon and sintered. The following examples are provided for additional examples only and are not intended to limit the scope of the present invention.

In order to synthesize a substantial amount of ink for antenna creation, reduction was carried out via wet chemistry. The chemistry of silver nanoinks was critical for antenna formation. To make suitable ink for printing using a pad printing cliché, 2 g of silver nanoparticles, suspended with remnant propylene glycol were mixed with a-terpineol and ethylcellulose (TEC). Propylene glycol was added as a viscosity modifier, departing from a traditional alcohol technique. Finally, the ink was manually stirred with a glass stir rod to break up loosely clumped nanoparticles and allow the ethylcellulose to completely disperse in solvent.

### Example 8

### Antenna Printing Process

Pad printing (or gravure-offset printing) was the chosen method printing for antennas. Pad printing systems consist of a cliché, a silicone pad, and a doctor blade. First, ink was applied to the cliché, and then the doctor blade wiped the ink over the grooves in the cliché, creating a positive image of the antenna. Approximately 0.1 mL of silver nanoinks was used for every 5 high-frequency antenna patterns created. A 2×3 cm sheet of thin Kapton HN50 (Dupont) was then placed on the silicone pad and the ensemble was pressed onto the cliché, creating a system of direct transfer of ink. Lastly, the antenna was sintered between 200-300° C. After approximately 10 minutes, the antennas would turn from a purple-grey to a bright white color on the exposed side and a silver color on the Kapton side. To modify the nanoinks to other printing processes, the amount of propylene glycol in the inks was changed.

### Example 9

### Preparation of Eudragit Substrates

Eudragit FS30D was supplied by Evonik (formerly Degussa), 1 mL of FS30D was used to completely cover high frequency antennas. The resulting average thickness of the coat is approximately 1 mm. Adjusting the amount of FS30D that was used to coat the antenna controlled the thickness of the substrate.

Eudragit S100 was also used, comprised of 82.5 mL isopropanol, 5 mL water, and 12.5 g S100. Talc was added as varied between 0 and 12.5 g (0-100% of solids weight) and 0-2 mL Citroflex 2 (Morflex) plasticizer was also added.

Each Eudragit application was allowed to set for 3 hrs at 50° C. The setting time was variable and deemed complete when all Eudragit had transformed from a translucent liquid into a transparent solid.

### Example 10

### Antenna Patterns n Rigid Eudragit

Printed antennas on Kapton were sintered as previously described and the as-sintered ‘before’ resistance was measured, Eudragit FS30D was applied as specified to cover the entire antenna with ˜1 mm liquid.

Eudragit was then heated to 100° C. for 3 minutes to promote easier flow the quasi-melted Eudragit. The Eudragit/antenna were then wrapped face-down around a polypropylene tube the diameter of a ‘000-sized’ gelatin capsule. The Eudragit was completely cooled in the air prior to peeling off the Kapton. The ‘After’ resistance was measured.

### Example 11

### Antenna Patterns on Single-Layer Flexible Eudragit

Eudragit flexibility was measured by a few measurable parameters dealing with bending a dry, room temperature sheet. Both the angle and the radius of the bent substrate measured the bend of said Eudragit sheet. So a flat piece measured a 0 degree angle with no radius. A 90° sheet is explained with one end flush with a tabletop and the other end pointing normal to the tabletop.

The flexibility of Eudragit was altered by changing either the amount of Eudragit solution laid down (to a very thin section) or by diluting the solution. It is difficult to pipette a very small amount due to surface tension issues. Therefore, diluting the solution was our preferred approach. This dilution of the Eudragit solution was prepared by adding 7 mL of H₂O to every 10 mL of FS30D. The solution was then pipetted onto an antenna design on Kapton and heated to 50° C., and then the substrate was peeled from the Kapton.

### Example 12

### Antennas on Multi-Layer Flexible Eudragit

To modify the flexibility of Eudragit, experiments were run using three different methods:

Method A.

Citroflex 2 plasticizer was dispersed in dilute FS30D as an oil-in-water that could be ‘finely separated’. Coagulations of with FS30D with Citroflex 2 were created to a limited degree and separated from solution manually. 0.5 mL of the solution was then pipetted evenly onto an antenna design on Kapton and heated to 50° C. The substrate was then peeled from the Kapton.

Method B.

Aquacoat® CPD (FMC Biopolymer)—a type of cellulose actetate phthalate (CAP) enteric coating—was mixed with FS30D. The solution was prepared by adding equal parts CAP and FS30D. 0.5 mL of the CAP-FS30D solution was then pipetted evenly onto an antenna on Kapton, heated to 50° C., and the substrate was peeled from the Kapton.

Method C.

The CAP-FS30D method listed above was also used to create a multi-layer Eudragit substrate. 0.2 mL of Eudragit FS30D solution was first pipetted onto an antenna pattern on Eudragit and heated at 50° C. until the FS30D was dry, with the intent of using the tackier Eudragit to pull off the maximum amount of the antenna. 0.5 mL of the CAP-FS30D solution was then pipetted evenly onto the FS30D antenna on Kapton, heated to 50° C., and the multi-layer substrate was peeled from the Kapton.

### Example 13

### Dissolution of Eudragit Substrates

Eudragit dissolution was tested in artificial gastric fluid (AGF) and artificial gastrointestinal fluids (AGIF). Silver antennas were transferred to Eudragit utilizing the aforementioned methods. An AGIF was prepared using 10 mg pepsin and HCl was added to 120 mL H₂O until pH 2 was reached (Hack et al.). The system was neutralized with 2 g Na₂CO₃ to raise the pH to basic conditions, creating an artificial gastrointestinal juice (AGIF). To better mimic the duodenum and intestines, the AGIF also included 350 mg pancreatin, 350 mg bile, and 400 mg NaHCO₃, the last of which was to neutralize the acid to maintain a pH 7.

Antennas were placed in 20 mL and 120 mL AGF and AGIF. Immersion times of antennas were 3 hrs and 15 hrs in AGIF. The Eudragit samples were dissolved and the antennas were allowed to remain in solution.

A “Perkin-Elmer Plasma 3200” inductively couple plasma-atomic emission spectroscope (ICP-AES) was used as the analysis system. ICP-AES provides an output of the amount of silver released into solution following dissolution in artificial gastric juices. This output is measured in parts per million and is calibrated against known standards. In our procedure, a 1000 ppm standard is diluted down to 100, 10, 1, and then 0.1 solutions by precisely adding 1.9964 mL of 1000 ppm solution to 17.9676 mL of Nanopure water. High precision in the calibration can provide a least-squares coefficient greater than 0.9999, which is used for precise calibration of the ICP-AES.

While various embodiments of the present invention have been shown and described herein, it will be obvious that such embodiments are provided by way of example only. Numerous variations, changes and substitutions may be made without departing from the invention herein. Accordingly, it is intended that the invention be limited only by the spirit and scope of the appended claims.

The previously described embodiments of the invention have many advantages, some of which will now be described. Not all of these advantages are required by all embodiments of the invention.

A first advantage of the invention is that of open faces on the surface of polymer protected particles, which is evident in AFM images. These open faces allow metal particles to maintain metal-to-metal contact. The particles no longer necessitate thermal agitation to move polymer and allow greater conductivity at both lower and higher temperatures than with non-open-faced particles. The protective polymer used can be any that binds to metal particles or metal ions. Such polymers include polyvinyl pyrrolidone or polyvinyl alcohol. Other short chain molecules could also be used, such as oligomers or proteins.

Polymer protected particles of various sizes can be made according to embodiments of the invention. For example, the polymer protected particles can be nanoparticles or microparticles or smaller.

When the protective polymer MW is small enough (shorter chain), the open faces can be created, thus exposing the conductor surfaces, In the present invention, a polymer with a MW of 10,000 was sufficient for the creation of open faces on metal nanoparticles. The end-to end distance can also define chain length, where an end-to-end distance of 3.2 nm (calculated using ideal conditions) is sufficient to produced open faces. A radius of gyration of 2.4 nm for a protective polymer also appears to be sufficient for the creation of open faces. These open faces allow for conductivity below that reported in the literature at temperatures below the metallization or sintering temperature of pure metal nanoparticles [compare to Dearden et al. (2005)]. Any protective molecule whose size will shrink considerably upon drying or partial-drying is sufficient for the creation of the open faces.

A short chain particle has proven useful in the embodiment mentioned here due to the relative sizes of particle to molecule. A size ratio greater than 10:1 (final nanoparticle to protective molecule size ratio) is used in the present embodiment.

The bimodally protected particles will also create size distributions that appear unimodal, but may be bimodal with protective agent on both particles. The size distribution can be controlled by the amount of protective agent added, the MW or size or the protective agent, and the reaction chemistry. When the protective agent concentration (of any MW) falls to a critical level (1:1 mass ratio, for example), the particle size distribution will tend towards larger sizes.

The degree of agglomeration can also affect the conductivity. Higher degrees of agglomeration were affected by longer chain particles than short chain particles. Agglomeration can be controlled by using the appropriate solution molarity. The concentration of metal nanoparticles in water also affects the final nanoparticle properties. A concentration of approximately 0.1M is a general upper limit to which usable nanoparticles will form without gelling or agglomeration that will prevent the particles from being used in conductive inks or pastes. Therefore, inks can be made by using nanoparticle synthesis with a concentration as high as 0.3 M.

In this embodiment of wet chemistry production of metal nanoparticles, we found that simple addition of pH increasing reagents, such as NaOH, could be used to create reclaimable silver nanoparticles suitable for printing as an ink. The literature has inquired that perhaps sodium carbonate could be used to create silver nanoparticles, but our efforts using that specific chemical could not create reclaimable particles; instead, that formulation produced a gel from which no reasonably conductive nanoink could be made.

The wet chemistry process described here has typically less final PVP concentration than comparable methods in the literature. Additionally, the −2% by mass remaining PVP in bimodal systems appears is an additional advantage of the bimodal or low MW PVP protection process. This appears due to the lower degree of entanglement of short chain protective agents, which are too short to produce trains, curls, and so forth that could entangle with other chains and prevent their removal following reaction.

Furthermore, bimodal protective agents allowed control over final ink characteristics, including post-centrifuge or settling compaction of particles. An easily pad-printable ink could be produced using 1:5 to 1:1 ratios of PVP40:PVP10 that allowed for excellent conductivity post heat treatment. At T<150° C., the magnitude of electrical conductivity difference between these bimodal PVP particles and standard unimodal particles was as much as 10⁶. These striking difference also translated into shorter sintering times for particles, presumably due to less interference from PVP (as they necessitate thermal agitation to move from nanoparticles surfaces).

This process is expandable to other possible nanoparticles, including copper, gold, platinum, iron, nickel, magnesium, platinum, palladium, cobalt, aluminum, chromium, and many other transition metals or other metallic species and any compounds therein that can bind to protective agents of various molecular weight and can be found to have open faces upon drying. The use of non-polymeric protective agents, or ones generally known as ligands, etc., that can produced bimodally protected particles are of significant use as well. One could also consider the use of trimodally (or higher order) protected particles depending on how one seeks to stabilize particles in solution and in a nanoink formulation and create lower resistivity in dried, cured, or sintered nanoinks. That some protective agents may allow only for microparticles (greater than the nanometer range) could be significant should electrical conductivity, size, and/or surface properties be affected through the use of shorter chain agents.

The process may also be extended to non-metallic particles that would benefit from open faces and/or size restraints. For example, a polymer nanoparticle may benefit from having open faces that can contact other polymer nanoparticles and allow for melting or coalescence upon application of heat, leaving a porous network of particles (a porous film) that could be used in lightweight polymer applications or allow for retention of inks or other fluids.

By use of binding agents that evaporate or are already used in the pharmaceutical industry, these particles can be sintered to create ingestible, biocompatible inks. The sintered properties or silver nanoparticles, for example, produce silver traces that leach minimal amounts of silver into simulated gastric fluids. For example, use of pharmaceutical grade ethylcellulose or carboxymethylcellulose with the proper solvent, such as a-terpineol, gives a functional ink for pad or screen printing. Other ink modifiers can be added such as release agents, tack modifiers, surfactants, rheology modifers, colorants, and so forth.

The particles can then be printed on or transferred to a biocompatible substrate. The biocompatible substrate can include biodegradable substrates that dissolve in the human body. High glass-transition or melting temperature substrates are useful for curing or sintering of metal particles. Substrates that are pH sensitive are also useful for ingestion in the lower GI tract while remaining stable in the upper GI tract. With electronics printed using metal, conductive polymer, or carbon particles, these substrates can be used to create ingestible electronics. A metallization treatment (such as sintering) that produces a continuous foil is sufficient to prevent release of particles into solution, fostering the creation of a biocompatible and ingestible electronic system (such as antenna/inductor and substrates, resistor and substrate, or capacitor and substrate). Additionally, a process wherein particles are trapped within a biocompatible binding agent or coated with another metal or polymer to trap particles during the duration of ingestion may be used here as well.

The invention has been described hereinabove with reference to the accompanying drawings, in which preferred embodiments of the invention are shown. Unless otherwise defined, all technical and scientific terms used herein are intended to have the same meaning as commonly understood in the art to which this invention pertains and at the time of its filing. Although various methods and materials similar or equivalent to those described herein can be used in the practice or testing of the present invention, suitable methods and materials are described. However, the skilled should understand that the methods and materials used and described are examples and may not be the only ones suitable for use in the invention.

Moreover, it should also be understood that any temperature, weight, volume, time interval, pH, salinity, molarity or molality, range, concentration and any other measurements, quantities or numerical figures expressed herein are intended to be approximate and not an exact or critical figure unless expressly stated to the contrary.

Further, any publications, patent applications, patents, and other references mentioned herein are incorporated by reference in their entirety as if they were part of this specification. However, in case of conflict, the present specification, including any definitions, will control. In addition, as noted above, materials, methods and examples given are illustrative in nature only and not intended to be limiting.

Accordingly, this invention may be embodied in many different forms and should not be construed as limited to the illustrated embodiments set forth herein. Rather, these illustrated embodiments are provided so that this disclosure will be thorough, complete, and will fully convey the scope of the invention to those skilled in the art. Therefore, in the specification set forth above there have been disclosed typical preferred embodiments of the invention, and although specific terms are employed, the terms are used in a descriptive sense only and not for purposes of limitation. The invention has been described in some detail, but it will be apparent that various modifications and changes can be made within the spirit and scope of the invention as described in the foregoing specification and as defined in the appended claims.

Any element in a claim that does not explicitly state “means for” performing a specified function, or “step for” performing a specified function, is not to be interpreted as a “means” or “step” clause as specified in 35 U.S.C. §112, ¶116. In particular, the use of “step of” in the claims herein is not intended to invoke the provisions of 35 U.S.C. §112, ¶116.

### BIBLIOGRAPHY

Arcidiacono S, Bieri N R, Poulilakos D. Grigoropolous C P. On the coalescence of gold nanoparticles. International Journal of Multiphase Flow. 2004; 30:979-994.
Balkrishnan R. Predictors of medication adherence in the elderly. Clinical Therapeutics, 1998; 20:764-771.
Bieri N R, Chung J, Haferl S E, Poulikakos D, Grigoropoulos C P. Microstructure by printing and laser curing of nanoparticle solutions. Applied Physics Letters. 2003; 82:3529-3531.
Brundle C R; Evans C A, Wilson S. Encyclopedia of Materials Characterization—Surfaces, Interfaces, Thin Films. Stoneham, Mass.: Butterworth-Heinemann, 1992; 442-443.
Cahn R W and Lifshin E. Concise Encyclopedia of Materials Characterization. New York, N.Y.: Pergamon Press. 1993; 423-426.
Chou K S and Lai Y S. Effect of PVP molecular weights on the formation of nanosized silver colloids. Materials Chemistry and Physics. 2004; 83:82-88.
Chou K S and Ren C Y. Synthesis of nanosized silver particles by chemical reduction method. Materials Chemistry and Physics. 2000; 64:241-246.
Das M, Dixit S, Khanna S K. Justifying the need to prescribe limits for toxic metal contaminants in food-grade silver foils. Food Additives and Contaminants. 2005; 22:1219-1223.
Dearden A L, Smith P J, Shin D Y, Reis N, Derby B, O'Brien P. A low curing temperature silver ink for use in ink-jet printing and subsequent production of conductive tracks. Macromolecular Rapid Communications. 2005; 26:315-318.
Diaz E, Levine H B, Sullivan M C, Sernyak M J, Hawkins K A, Cramer J A, Woods S W. Use of the Medication Event Monitoring System to estimate medication compliance in patients with schizophrenia. Journal of Psychiatry Neuroscience. 2001; 26:325-329.
Drake P L and Hazelwood K J. Exposure-related health effects of silver and
silver compounds: A review. Annals of Occupational Hygiene. 2005; 49:575-585.
Farmer K C. Methods for measuring and monitoring medication regimen adherence in clinical trials and clinical practice. Clinical Therapeutics. 1999; 21:1074-1090
Flory P J. Principles of Polymer Chemistry. Ithaca, N.Y.: Cornell University Press. 1953; 428-430.
Fung M C and Bowen D L. Silver products for medical indications: risk-benefit assessment, Journal of Toxicology: Clinical Toxicology. 1996; 34:119.
Hughes C M. Medication non-adherence in the elderly. Drugs Aging. 2004; 21:793—-811.
Hummel R E. Electronic Properties of Materials, 3^{rd} Ed. New York, N.Y.: Springer. 2003; 245.
Jeong S, Kim D, Lee S, Park B K, Moon J. Fabrication of organic thin-film transistors based on ink-jet printed silver electrodes. Molecular Crystals and Liquid Crystals. 2006; 459:35-43.
Lansdown A B G. Critical observations on the neurotoxicity of silver. Critical Reviews in Toxicology. 2007; 37:237—-250.
Lee H H, Chou K S, Huang K C. Inkjet printing of nanosized silver colloids. Nanotechnology. 2005; 16:2436-2441.
Lee J K, Jun B H, Kim T H, Joung J. Direct synthesis and inkjetting of silver nanocrystals toward printed electronics. Nanotechnology. 2006:17:2424-2428.
Lofton C and Sigmund W. Mechanisms controlling crystal habits of gold and silver colloids. Advanced Functional Materials. 2005; 15:1197-1208.
Magdassi S, Bassa A, Vinetsky Y, Kamyshny A. Silver nanoparticles as pigments for water-based inkjet inks. Chemistry of Materials. 2003; 15:2208-2217.
Magonov S, Elings; V, Whanbo H. Phase imaging and stiffness in tapping-mode atomic force microscopy. Surface Science. 1997; 375:L385-L391.
Malcolm R, Currey H S, Mitchell M A, Keil J E. Silver acetate gum as a deterrent to smoking. Chest. 1986; 90:107-111.
McDonald H P, Garg A X, Haynes R B. Interventions to enhance patient adherence to medication prescriptions: Scientific review. Journal of the American Medical Association, 2002; 288:2868-79.
Mazzone A M. Coalescence of metallic nanoclusters: a study by molecular dynamics. Philosophical Magazine B. 2000; 80:95-111.
Moon K S, Dong H, Maric R, Pothukuchi S, Hunt A, Li Y, Wong C P. Thermal behavior of silver nanoparticles for low-temperature interconnect applications. Journal of Electronic Materials. 2005; 34:168-175.
Moussy F and Harrison D J. Prevention of the rapid degradation of subcutaneously implanted Ag/AgCl reference electrodes using polymer coatings. Analytical Chemistiy. 1994; 66:674-679.
Neudeck W G and Pierret R F, Introduction to Microelectronic Fabrication. Reading, Mass.: Addison-Wesley Publishing Company. 1993; 72.
Nugent C, Finaly D, Davies R, Paggetti C, Tamburini E, Black N. Can technology improve compliance to medication? From Smart Homes to Smart Care. Amsterdam, The Netherlands: IOS Press. 2005; 65-72.
Pastoriza-Santos I, Liz-Marzan L M. Formation of PVP-protected metal nanoparticles in DMF. Langmuir. 2002; 18:2888-2894.
Pradhan N, Pal A, Pal T. Silver nanoparticle catalyzed reduction of aromatic nitro compounds. Colloids and Surfaces A: Physiochemical and Engineering Aspects. 2002:196:247-257.
Pudas M, Hagberg J, Leppavuori S. Printing parameters and ink components affecting ultra-fine-line gravure-offset printing for electronic applications. Journal of the European Ceramic Society. 2004; 24:2934-2950.
Pudas M, Hagberg J, Leppavuori S, Elsey K, Logan A. Methods for the evaluation of fine-line offset gravure printing inks for ceramics. Coloration Technology. 2004; 120:119-126.
Reddy M J, Sreekanth T, Chandreshekar M, RAO UVS. Ion transport and electrochemical cell characteristic studies of a new (PVP 1 NaNO₃) polymer electrolyte system. Journal of Materials Science. 2000; 35:2841-2845.
Ren X, Meng X, Chen D, Tang F, Jiao J. Using silver nanoparticle to enhance current response of biosensor. Biosensors and Bioelectronics. 2005; 21:433-437.
Sato T, Sato A, Arai T. Adsorption of polyvinylpyrrolidone on titanium dioxide from binary solvents (methanol/water) and its effect on dispersion stability. Colloids and Surfaces A: Physiochemical and Engineering Aspects. 1998; 142:117-120.
Shin H S, Yan H J, Kim S B, Lee M S. Mechanism of growth of colloidal silver nanoparticles stabilized by PVP in Li-irradiated silver nitrate solution. Journal of Colloids and Interface Sciences. 2004; 274:89-94.
Smitha S L, Nissamudeen K M, Philip D, Gopchandran K G. Studies on surface plasmon resonance and photoluminescence of silver nanoparticles. Spectrochimica Acta, Part A: Molecular and Biomolecular Spectroscopy. 2007;Article in Press.
Sperling L H. Introduction to Physical Polymer Science, e Ed. Hoboken, N.J.: Wiley. (2001) p. 6.
Sun Y, Yin Y, Mayers B T, Herricks T, X is Y. Uniform silver nanowires synthesis by reducing AgNO₃ with ethylene glycol in the presence of seeds and PVP. Chemistry of Materials. 2002; 14:4736-4745.
Van Hyning D L, Klemperer W G, Zukoski C F. Silver nanoparticle formation: predictions and verification of the aggregative growth model. Langmuir. 2001:17:3128-3135.
Van Hyning D L and Zukoski C F. Formation mechanisms and aggregation behavior of borohydride reduced silver particles. Langmuir. 1998; 14:7034-7046.
Wang H, Qiao X, Chen J, Wang X, Ding S. Mechanisms of PVP in the preparation of silver nanoparticles. Materials Chemistry and Physics. 2005; 94; 449-453.
Winnick S, Lucas D O, Hartman A L, Toll D. How do you improve compliance? Pediatrics. 2005; 115:e718-e724.
Yin B. Ma H, Wang S, Chen S. Electrochemical synthesis of silver nanoparticles under protection of PVP. Journal of Physical Chemistry. 2003; 107:8898-8904.
Yu H, Flores G, Reza S, Irby G, Meka V. Peterson, D M, Batich C, Euliano N, Bashirullah R. Feasibility study of printed capsule antennas for medication compliance monitoring. Biomedical Circuits and Systems Conference, 2007. 2007:41-44.
Zhang Z, Zhao B, Hu L. PVP Protective Mechanism of Ultrafine Silver Powder Synthesized by Chemical Reduction Processes. Journal of Solid State Chemistry. 1996; 121:105-110.
Zhu H and Averback R S. Sintering processes of two nanoparticles: a study by molecular-dynamics simulations. Philosophical Magazine Letters. 1996; 73:27-33

1-67. (canceled)

68. A composition comprising a plurality of electrically conductive nanoparticles having a coating on a surface thereof, wherein the coating prevents the particles from agglomerating when the particles are in solution and allows adjacent particle surfaces to be in direct physical contact when the particles are not in solution.

69. The composition of claim 68, wherein the coating includes a plurality of polymer molecules having different molecular weights and the particles have a particle size of about 1 nm to about 200 nm.

70. The composition of claim 68, wherein the coating includes a first polymer having a first average molecular weight and a second polymer having a second average molecular weight, the second average molecular weight being greater than the first average molecular weight.

71. The composition of claim 70, wherein the first and second polymers are polyvinylpyrrolidone.

72. The composition of claim 71, wherein the first polymer, PVP10, is polyvinylpyrrolidone having an average molecular weight of 10,000 and the second polymer, PVP40, is polyvinylpyrrolidone having an average molecular weight of 40,000.

73. The composition of claim 72, wherein the ratio of PVP40:PVP10 is 1:10 to 10:1.

74. The composition of claim 72, wherein the ratio of PVP40:PVP10 is 1:1 to 1:5.

75. The composition of claim 74, wherein the particles are sinterable at or below 190 degrees C. to form an electrically conductive film having an electrical resistivity below 1 Ω-cm at 25 degrees C.

76. A process for making polymeric coated nanoparticles, the process comprising:
adding a metal ion salt to a solution comprising a first polymer having a first average molecular weight and a second polymer having a second average molecular weight, the second average molecular weight being greater than the first average molecular weight, to form a metal ion salt solution;
forming a reaction solution by reducing the valency of the metal ions in the metal ion salt solution with a reducing agent;
increasing the pH of the reaction solution;
removing any unreacted reagents; and
allowing a suspension of colloidal particles comprising a metal core coated with the first polymer and second polymer to form.

77. The process of claim 76, wherein the metal ion salt comprises silver.

78. The process of claim 77, wherein the metal ion salt is silver nitrate.

79. The process of claim 76, wherein the pH is increased using a base.

80. The process of claim 79, wherein the base is sodium hydroxide, the metal ion salt is silver nitrate, and a mass ratio of sodium hydroxide to silver nitrate is 1:30 to 30:1.

81. The process of claim 76, wherein the first and second polymers are polyvinylpyrrolidone.

82. The process of claim 81, wherein the first polymer, PVP10, is polyvinylpyrrolidone having an average molecular weight of 10,000 and the second polymer, PVP40, is polyvinylpyrrolidone having an average molecular weight of 40,000.

83. The process of claim 82, wherein the ratio of PVP40:PVP10 is 1:10 to 10:1.

84. The process of claim 82, wherein the ratio of PVP40:PVP10 is 1:1 to 1:5.

85. The process of claim 76, wherein:
the first polymer, PVP10, is polyvinylpyrrolidone having an average molecular weight of 10,000 and the second polymer, PVP40, is polyvinylpyrrolidone having an average molecular weight of 40,000;
the ratio of PVP40:PVP10 is 1:1 to 1:5; and
the pH is increased using sodium hydroxide, the metal ion salt is silver nitrate, and a mass ratio of sodium hydroxide to silver nitrate is 1:30 to 30:1.

86. An electrical device comprising:
a substrate having an electrically conductive film positioned thereon, the electrically conductive film comprising a plurality of electrically conductive nanoparticles coated with a polymeric coating in such a way that adjacent electrically conductive nanoparticle surfaces are in direct physical contact through an opening in the polymeric coating, the polymeric coating including a plurality of polymers having different molecular weights.

87. The electrical device of claim 86, wherein the polymeric coating prevents agglomeration of the particle surfaces when the particle surfaces are in solution.

88. The electrical device of claim 86, wherein the polymeric coating includes a first polymer having a first average molecular weight and a second polymer having a second average molecular weight, the second average molecular weight being greater than the first average molecular weight.

89. The electrical device of claim 88, wherein the first and second polymers are polyvinylpyrrolidone.

90. The electrical device of claim 89, wherein the first polymer, PVP10, is polyvinylpyrrolidone having an average molecular weight of 10,000 and the second polymer, PVP40, is polyvinylpyrrolidone having an average molecular weight of 40,000.

91. The electrical device of claim 90, wherein the ratio of PVP40:PVP10 is 1:10 to 10:1.

92. The electrical device of claim 90, wherein the ratio of PVP40:PVP10 is 1:1 to 1:5.

93. The electrical device of claim 86, wherein the electrically conductive film has an electrical resistivity below 1 Ω-cm at 25 degrees C.

94. The electrical device of claim 86, wherein a solubility of the substrate is pH dependent.

95. The electrical device of claim 94, wherein the substrate is soluble at a pH above 5.

96. A process for making an electronic device, the process comprising:
positioning a colloidal solution of polymeric coated electrically conductive particles on a substrate, wherein the polymeric coating prevents the particles from agglomerating when the particles are in solution;
heating the colloidal solution on the substrate to bring adjacent electrically conductive particles into direct physical contact through an opening in the polymeric coating; and
sintering the colloidal solution on the substrate at a temperature at or below 190 degrees C., thereby forming an electrically conductive film.

97. The process of claim 96, wherein the polymeric coating includes a first polymer having a first average molecular weight and a second polymer having a second average molecular weight, the second average molecular weight being greater than the first average molecular weight.

98. The process of claim 97, wherein the first and second polymers are polyvinylpyrrolidone.

99. The process of claim 98, wherein the first polymer, PVP10, is polyvinylpyrrolidone having an average molecular weight of 10,000 and the second polymer, PVP40, is polyvinylpyrrolidone having an average molecular weight of 40,000.

100. The process of claim 99, wherein the ratio of PVP40:PVP10 is 1:10 to 10:1.

101. The process of claim 99, wherein the ratio of PVP40:PVP10 is 1:1 to 1:5.

102. The process of claim 96, wherein the electrically conductive film has an electrical resistivity below 1 Ω-cm at 25 degrees C.
